(19) United States
(12) Patent Application Publication
(10) Pub. No.: US 2017/0136669 A1
(43) Pub. Date: May 18, 2017

(54) MOLDING APPARATUS FOR SEMICONDUCTOR PACKAGE FABRICATION AND METHOD OF MOLDING SEMICONDUCTOR PACKAGE USING THE SAME

(71) Applicant: Samsung Electronics Co., Ltd., Suwon-si (KR)

(72) Inventors: Kwang won Choi, Suwon-si (KR); Jong-woo Park, Seongnam-si (KR); Seung jin Cheon, Chungcheongnam-do (KR); Hyun-suk Chun, Yongin-si (KR); In hak Baick, Yongin-si (KR)

(21) Appl. No.: 15/295,279

(22) Filed: Oct. 17, 2016

(30) Foreign Application Priority Data
Nov. 12, 2015 (KR) 1020150159006

(51) Int. Cl. B29C 45/34; H01L 21/52; H01L 21/66; H01L 21/48; B29C 45/14; H01L 21/56

(52) U.S. Cl. CPC B29C 45/34; B29C 45/14819; H01L 21/565; H01L 22/12; H01L 21/4853; H01L 21/52; B29L 2031/34

(57) ABSTRACT

A molding apparatus for semiconductor package fabrication includes a bottom mold on which a molding object can be mounted, a top mold on the bottom mold including the molding object that is mounted on the bottom mold, and a side mold on one side of the bottom mold and the top mold. The side mold has a plurality of air vent holes. A cavity into which a molding material can be injected and made to flow is provided between the bottom mold and the top mold.

### CROSS-REFERENCE TO RELATED APPLICATION

This U.S. non-provisional application claims priority under 35 USC §119 to Korean Patent Application No. 10-2015-0159006, filed on Nov. 12, 2015, in the Korean Intellectual Property Office, the contents of which are herein incorporated by reference in their entirety.

### BACKGROUND

Some embodiments of the inventive concepts relate to a molding apparatus for semiconductor package fabrication and a method of molding a semiconductor package using the same. More particularly, some embodiments of the inventive concepts relate to a molding apparatus for semiconductor package fabrication, which allows uniform flow of a molding material, and a method of molding a semiconductor package using the same.

In fabricating a semiconductor package, a process of molding a semiconductor chip to protect the semiconductor chip is needed. The molding process may be performed by arranging the semiconductor chip in a mold, and then filling an inside of the mold with a molding material by supplying the molding material into the mold such that the molding material flows through the mold. In the molding process of the semiconductor chip, there is a need for uniform flow of the molding material.

### SUMMARY

Some embodiments of the inventive concepts provide a molding apparatus for semiconductor package fabrication, which allows uniform flow of a molding material.

Some embodiments of the inventive concepts also provide a method of molding a semiconductor package, which allows uniform flow of a molding material using the molding apparatus for semiconductor package fabrication as set forth above.

According to an aspect of the inventive concepts, there is provided a molding apparatus for semiconductor package fabrication. The molding apparatus includes: a bottom mold on which a molding object can be mounted; a top mold on the bottom mold including the molding object that is mounted; and a side mold on one side of the bottom mold and the top mold, the side mold having a plurality of air vent holes. A cavity is provided between the bottom mold and the top mold. The cavity is capable of having a molding material injected therein and made to flow therein.

According to another aspect of the inventive concepts, there is provided a molding apparatus for semiconductor package fabrication. The molding apparatus includes: a bottom mold on which a molding object can be mounted; a top mold on the bottom mold including the molding object that is mounted; a molding material supplier capable of supplying a molding material into a cavity between the bottom mold and the top mold; a side mold on one side of the bottom mold and the top mold, the side mold having a plurality of air vent holes; and an air sucking unit connected to the air vent holes of the side mold.

According to another aspect of the inventive concepts, there is provided a molding apparatus for semiconductor package fabrication. The molding apparatus includes: a bottom mold on which a molding object can be mounted, the molding object including a plurality of semiconductor chips on a printed circuit board or a wafer; a top mold on the bottom mold including the molding object that is mounted on the bottom mold; a molding material supplier in a central portion of one of the bottom mold and the top mold, the molding material supplier being able to supply a molding material into a cavity between the bottom mold and the top mold; a side mold on both sides of the bottom mold and the top mold or around the bottom mold and the top mold, the side mold having a plurality of air vent holes; an air sucking unit connected to the air vent holes of the side mold through an exhaust pipe; an air reservoir provided to the exhaust pipe which is connected to the air vent holes of the side mold; and a detachable air vent controlling member provided to the exhaust pipe at a front or rear end of the air reservoir.

According to another aspect of the inventive concepts, there is provided a method of molding a semiconductor package. The method includes: evaluating flow uniformity of a molding material based on air vent holes of a side mold; inserting an air vent controlling member into each of the air vent holes of the side mold; mounting a molding object on a bottom mold; tightly pressing a top mold and the side mold to the bottom mold including the molding object that is mounted on the bottom mold; molding the molding object with the molding material; and forming a molding layer on the molding object by separating the bottom mold, the top mold, and the side mold.

According to an aspect of the present inventive concepts, a molding apparatus for semiconductor package fabrication may include a bottom mold on which a molding object can be mounted, a top mold on the bottom mold, a side mold on at least one side of the bottom mold and the top mold, a cavity in at least one of the top mold and the bottom mold, and a plurality of air vent holes in the side mold. The plurality of air vent holds are arranged at regular intervals along the side mold.

According to the inventive concepts, the molding apparatus for semiconductor package fabrication includes the side mold having the plurality of air vent holes on at least one side of the bottom mold and the top mold. Therefore, the molding apparatus for semiconductor package fabrication can uniformly control flow of the molding material by controlling air flow in the air vent holes.

In addition, the molding apparatus for semiconductor package fabrication may include the detachable air vent controlling member in each of the air vent holes of the side mold, and the air vent controlling members may respectively include the sub-air vent holes having different sizes. Therefore, the molding apparatus for semiconductor package fabrication can uniformly control flow of the molding material by adjusting the sizes of the sub-air vent holes even without replacing the bottom mold and the top mold.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a cross-sectional view illustrating a molding apparatus for semiconductor package fabrication according to some embodiments of the present inventive concepts.

FIG. 2 is a plan view of a molding object of FIG. 1 according to some embodiments of the present inventive concepts.

FIG. 3 is a plan view of a bottom mold of FIG. 1 according to some embodiments of the present inventive concepts.

FIG. 4 is a plan view of the molding apparatus of FIG. 1 according to some embodiments of the present inventive concepts.

FIG. 5 is an exploded, perspective view of a molding apparatus for semiconductor package fabrication according to some embodiments of the present inventive concepts.

FIG. 6 is an exploded, perspective view illustrating air vent holes of a side mold and a controlling member of FIG. 6 according to some embodiments of the present inventive concepts.

FIGS. 7 and 8 are perspective views illustrating an air vent controlling member of FIG. 6 according to some embodiments of the present inventive concepts.

FIG. 9 is a cross-sectional view illustrating the air vent controlling member mounted in the side mold of FIG. 6 according to some embodiments of the present inventive concepts.

FIGS. 10A and 10B are exploded perspective views illustrating a molding process using the molding apparatus for semiconductor package fabrication of FIGS. 5 to 9.

FIG. 11 is an exploded, cross-sectional view illustrating a molding apparatus for semiconductor package fabrication according to some embodiments of the present inventive concepts.

FIG. 12 is an exploded, cross-sectional view illustrating a molding apparatus for semiconductor package fabrication according to some embodiments of the present inventive concepts.

FIG. 13 is a cross-sectional view illustrating a molding apparatus for semiconductor package fabrication according to some embodiments of the present inventive concepts.

FIG. 14 is a cross-sectional view illustrating a molding apparatus for semiconductor package fabrication according to some embodiments of the present inventive concepts.

FIG. 15 is a plan view illustrating the molding apparatus of FIG. 14 according to some embodiments of the present inventive concepts.

FIG. 16 is a cross-sectional view illustrating a molding apparatus for semiconductor package fabrication according to some embodiments of the present inventive concepts.

FIG. 17 is a cross-section view illustrating injection of a molding material into a cavity of FIG. 16 according to some embodiments of the present inventive concepts.

FIG. 18 is a cross-sectional view illustrating a molding apparatus for semiconductor package fabrication according to some embodiments of the present inventive concepts.

FIG. 19 is a plan view illustrating the molding apparatus of FIG. 18 according to some embodiments of the present inventive concepts.

FIG. 20 is a perspective view of the molding apparatus of FIG. 18 according to some embodiments of the present inventive concepts.

FIG. 21 is a flowchart of a method of molding a semiconductor package according to some embodiments of the present inventive concepts.

FIGS. 22A to 22D are diagrams illustrating simulation results obtained by evaluating flow uniformity of a molding material depending upon air vent holes of a side mold of FIG. 21.

FIGS. 23A and 23B are cross-sectional views illustrating semiconductor packages fabricated using a molding apparatus for semiconductor package fabrication according to some embodiments of the present inventive concepts.

FIGS. 24A to 24D are cross-sectional views illustrating semiconductor packages fabricated using a molding apparatus for semiconductor package fabrication according to some embodiments of the present inventive concepts

FIG. 25 is a schematic, plan view of a semiconductor module including a semiconductor package according to some embodiments of the present inventive concepts.

FIG. 26 is a schematic, block diagram of a card including a semiconductor package according to some embodiments of the present inventive concepts.

FIG. 27 is a schematic, block diagram of an electronic circuit board including a semiconductor package according to some embodiments of the present inventive concepts.

FIG. 28 is a schematic, block diagram of an electronic system including a semiconductor package according to some embodiments of the present inventive concepts.

FIG. 29 is a schematic, block diagram of an electronic system including a semiconductor package according to some embodiments of the present inventive concepts.

FIG. 30 is a schematic, perspective view of an electronic device including a semiconductor package according to some embodiments of the present inventive concepts.

### DETAILED DESCRIPTION OF EMBODIMENTS

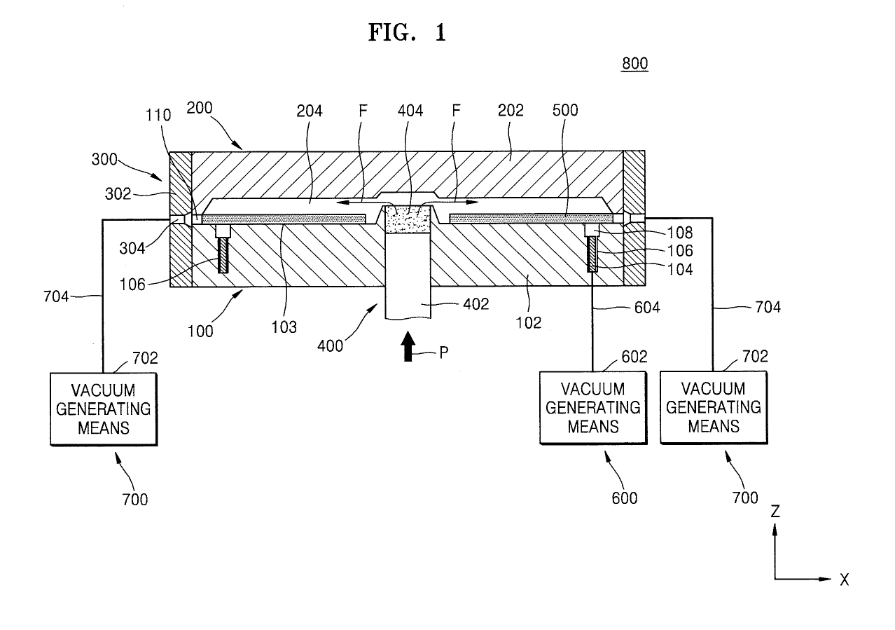

FIGS. 1 to 4 are diagrams illustrating a molding apparatus for semiconductor package fabrication according to some embodiments of the present inventive concepts.

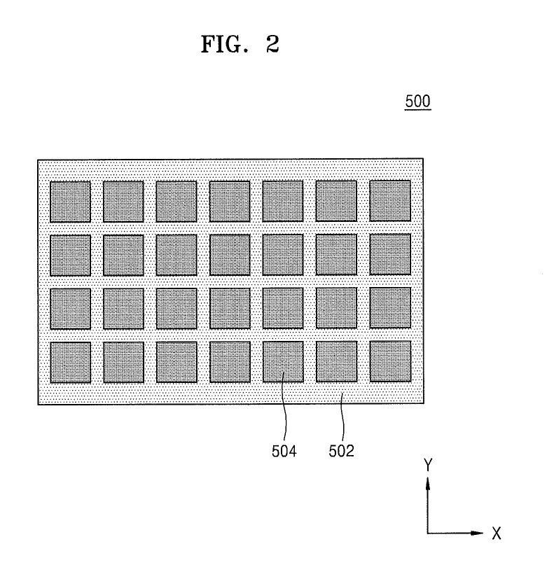

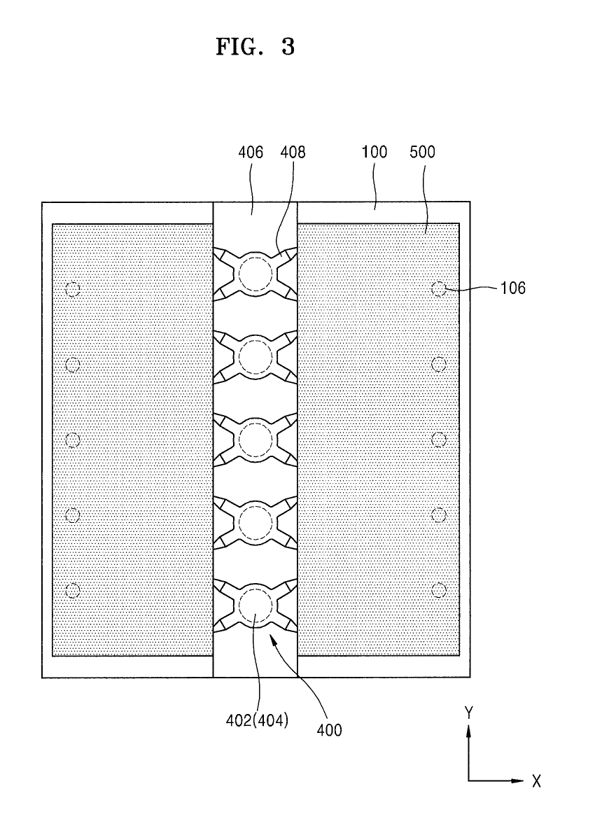

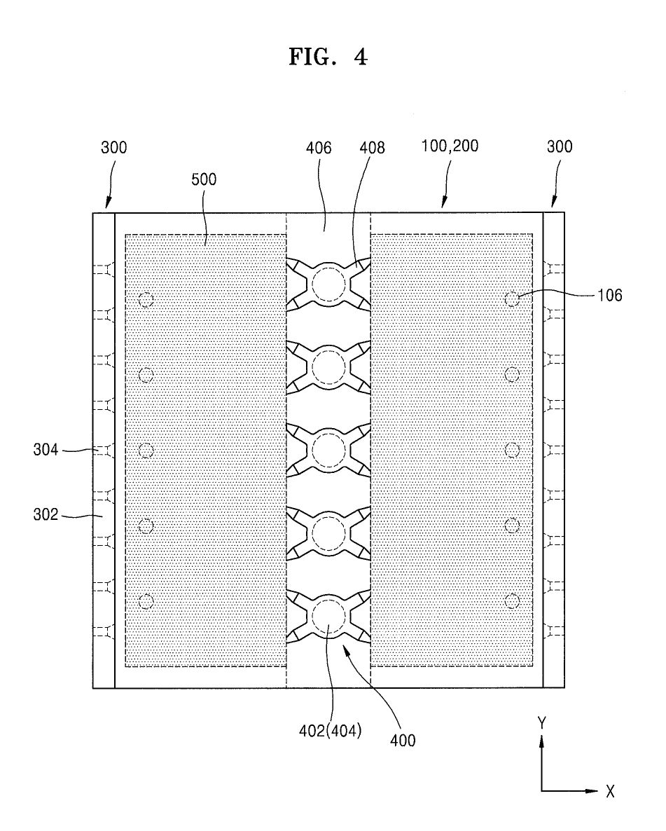

Specifically, FIG. 1 is a cross-sectional view illustrating a molding apparatus 800 for semiconductor package fabrication, FIG. 2 is a plan view of a molding object 500 of FIG. 1, FIG. 3 is a plan view of a bottom mold 100 of FIG. 1, and FIG. 4 is a plan view of the molding apparatus 800 for semiconductor package fabrication of FIG. 1.

In FIGS. 1 to 4, an X direction may be a flow direction of a molding material 404 in the cross-sectional view, a Y direction may be a direction that is perpendicular to the flow direction of the molding material 404 in the plan view, and a Z direction may be a direction that is perpendicular to the flow direction of the molding material 404 in the cross-sectional view of FIG. 1. In FIGS. 1 to 4, both sides of the molding apparatus 800 for semiconductor package fabrication may be symmetric with respect to a molding material supplier 400. The molding apparatus 800 may surround the molding material supplier 400.

The molding apparatus 800 for semiconductor package fabrication includes the bottom mold 100 on which the molding object 500 may be mounted. As illustrated in FIG. 2, the molding object 500 may include a plurality of semiconductor chips 504 on a printed circuit board 502. The bottom mold 100 may include a bottom mold body 102. A bottom cavity 103, in which the molding object 500 may be mounted, may be provided on an upper surface of the bottom mold body 102. That is, the bottom cavity 103 may be a recess in the surface of the bottom mold body 102.

The bottom mold body 102 may include a plurality of vacuum holes 106 which can secure the molding object 500 to the bottom mold body 102 by vacuum suction. The vacuum holes 106 may be connected to a first air sucking unit 600. The first air sucking unit 600 may include an exhaust pipe 604 connected to the vacuum holes 106, and a vacuum generating means 602. Since the vacuum holes 106 are connected to the first air sucking unit 600, the molding object 500 can be stably secured to the bottom mold body 102 by vacuum suction produced by the first air sucking unit 600.

The vacuum holes 106 may be located at a side opposite to a side into which the molding material 404 is injected. That is, the vacuum holes 106 may be positioned at outer edge regions of the bottom mold body 102. In FIG. 1, although the exhaust pipe 604 is shown as being connected to the vacuum hole 106 only at one side of the bottom mold body 102 for convenience, the exhaust pipe 604 is connected to all of the plurality of vacuum holes 106. A vacuum pin 104 may be located in the vacuum hole 106, the vacuum pin 104 may be inserted into the vacuum hole 106 to a height that is lower than the upper surface of the bottom mold body 102. A fine gap may be formed between the vacuum pin 104 and the vacuum hole 106.

The vacuum pin 104 may be moved up and down in the bottom mold body 102. When the vacuum pin 104 is moved up and down in the bottom mold body 102, the vacuum pin 104 may serve as a separation pin separating the molding object 500 from the bottom mold body 102 after completion of the molding process.

In addition, a vacuum buffering pocket 108 may be located in the vacuum hole 106 between the vacuum pin 104 and the upper surface of the bottom mold body 102. When the molding object 500 is secured to the bottom mold body 102 by vacuum suction produced by the first air sucking unit 600, the vacuum buffering pocket 108 results in the molding object 500 being more stably secured to the bottom mold body 102 by vacuum suction without deformation of the molding object 500.

The molding material supplier 400 capable of injecting or supplying the molding material 404 may be provided in a central portion of the bottom mold 100. The molding material supplier 400 may include the molding material 404, a plunger 402 capable of pressing the molding material 404, and a molding material flow path 408, for example, a runner or a gate, as illustrated in FIGS. 3 and 4, through which the molding material 404 flows. As shown in FIGS. 3 and 4, the molding material 404 and the plunger 402 may be provided in, for example, a plunger block 406.

The molding material 404 may be, for example, a resin, for example, an epoxy resin. The molding material 404 may be a solid molding material. When the molding material 404 is a solid molding material, the molding material 404 may be heated by a heating means (not shown), and the heated molding material 404 may be fluidized and be pressed by the plunger 402 as denoted by an arrow P of FIG. 1, whereby the molding material 404 may flow, as denoted by arrows F, into a cavity 204 between the bottom mold 100 and a top mold 200.

The molding apparatus 800 for semiconductor package fabrication includes the top mold 200 on the bottom mold 100 including the molding object 500 that is mounted thereon. The top mold 200 includes a top mold body 202. As described above, a cavity (top cavity) 204, into which the molding material 404 can be injected, may be provided on a surface of the top mold body 202. That is, the cavity 204 may be a recess formed in a bottom surface of the top mold 200. As shown in FIG. 1, an air flow path 110 may be located between the top mold body 202 and a portion of the bottom mold body 102 on which the molding object 500 is not mounted. That is, the air flow path 110 may be between an outermost edge of the top mold body 202 and an outermost edge of the top cavity 204 and between an outermost edge of the bottom mold body 102 and the outermost edge of the molding object 500

The molding apparatus 800 for semiconductor package fabrication includes a side mold 300, which has a plurality of air vent holes 304, on at least one side of the bottom mold 100 and the top mold 200. When the molding material supplier 400 is located in the central portion of the bottom mold 100, the side mold 300 may be located on both sides of the bottom mold 100 and the top mold 200. That is, the side mold 600 is positioned along the outermost edges of the top mold 200 and the bottom mold 100. The bottom mold 100, the top mold 200, and the side mold 300 may be a mold for molding the molding object 500.

After the top mold 200 is tightly pressed onto the bottom mold 200 including the molding object 500 that is mounted thereon, and the side mold 300 is tightly pressed to both sides of the bottom mold 100 and the top mold 200, the molding apparatus 800 for semiconductor package fabrication may perform a molding process.

The side mold 300 may include a side mold body 302 and the air vent holes 304. The air vent holes 304 having the same size (for example, the same diameter) may be arranged in the side mold body 302 at regular intervals in a direction (Y direction) perpendicular to the flow direction (X direction) of the molding material 404, as illustrated in FIG. 4.

The air vent holes 304 may be connected to a second air sucking unit 700. The second air sucking unit 700 may include an exhaust pipe 704 and a vacuum generating means 702. Since the air vent holes 304, which are arranged at regular intervals in the direction (Y direction) perpendicular to the flow direction (X direction) of the molding material 404 while having the same size, are connected to the second air sucking unit 700, air that flows out from between the bottom mold 100 and the top mold 200 can be more stably discharged during the molding process.

As described above, the molding apparatus 800 for semiconductor package fabrication may include the top cavity 204, into which the molding material 404 can be injected, between the bottom mold 100 and the top mold 200. In addition, the side mold 300 having the plurality of air vent holes 304 is provided on at least one side of the bottom mold 100 and the top mold 200.

In addition, as described above, the air vent holes 304 having the same size may be arranged at regular intervals in the direction (Y direction) perpendicular to the flow direction (X direction) of the molding material 404. The molding apparatus 800 for semiconductor package fabrication may improve flow of air flowing through the air vent holes 304 by adjusting sizes of the air vent holes 304 or intervals between the air vent holes 304 according to a kind or type of molding object 500 and properties of the molding material 404. Therefore, the molding apparatus 800 for semiconductor package fabrication allows uniform flow of the molding material 404 by arranging the air vent holes 304 in the side mold 300, thereby optimizing the molding process.

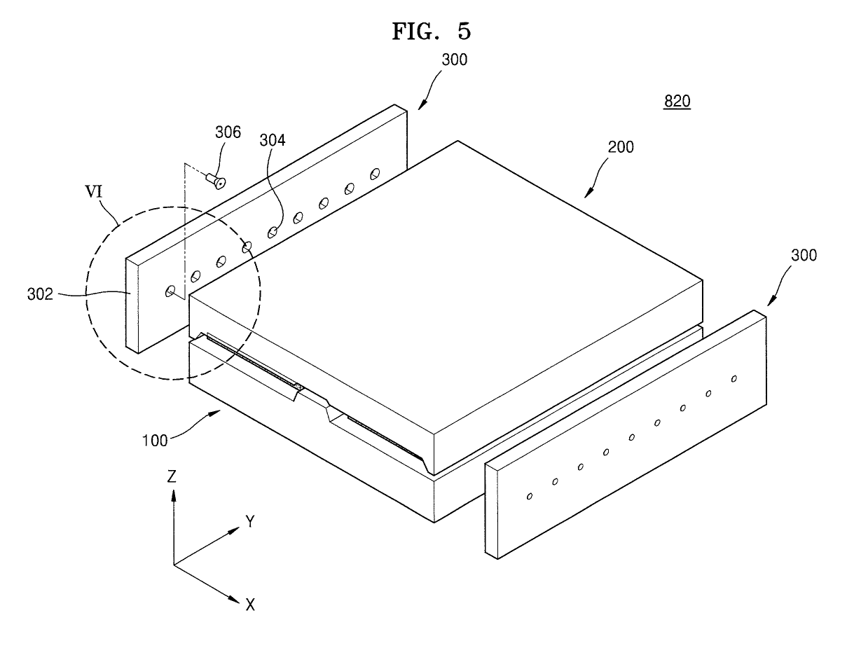

FIGS. 5 to 9 are diagrams illustrating a molding apparatus for semiconductor package fabrication according to some embodiments of the present inventive concepts.

Specifically, a molding apparatus 820 for semiconductor package fabrication of FIGS. 5 to 9 may be substantially similar to the molding apparatus 800 for semiconductor package fabrication of FIGS. 1 to 4, except that molding apparatus 820 for semiconductor package fabrication includes an air vent controlling member 306. In FIGS. 5 to 9, the same reference numerals as in FIGS. 1 to 4 may denote the same components as in FIGS. 1 to 4, and the same components will be briefly described or omitted for convenience.

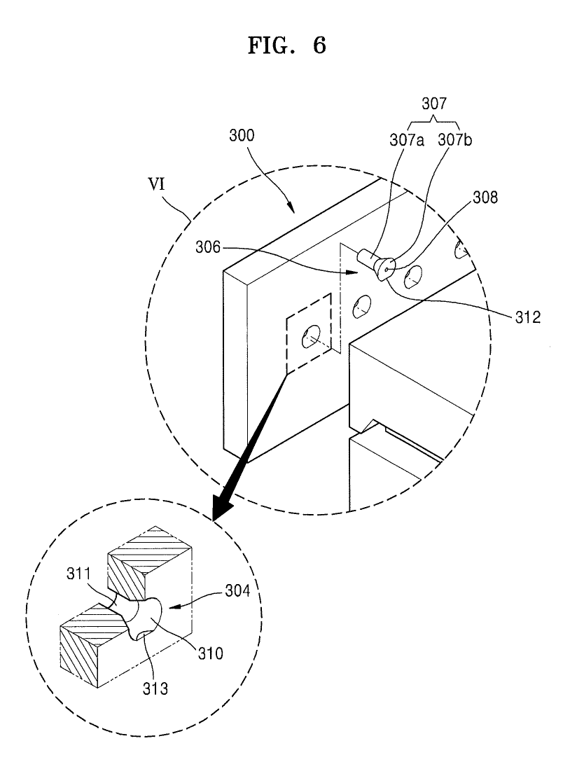

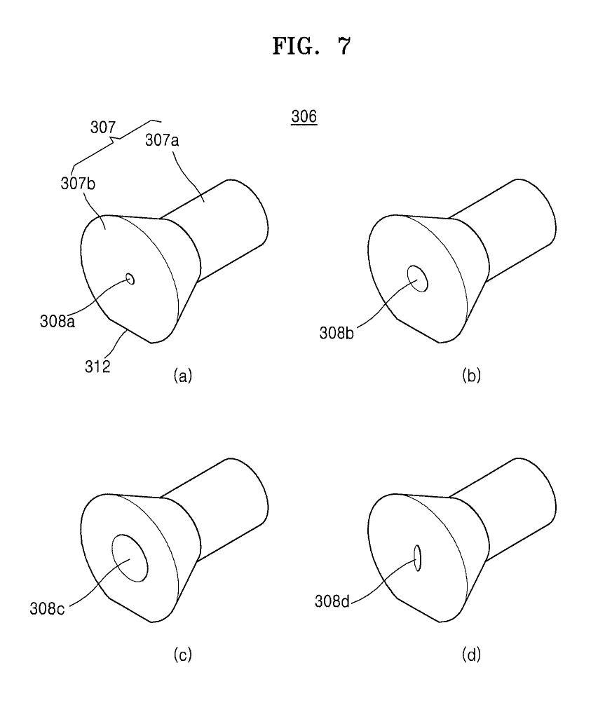

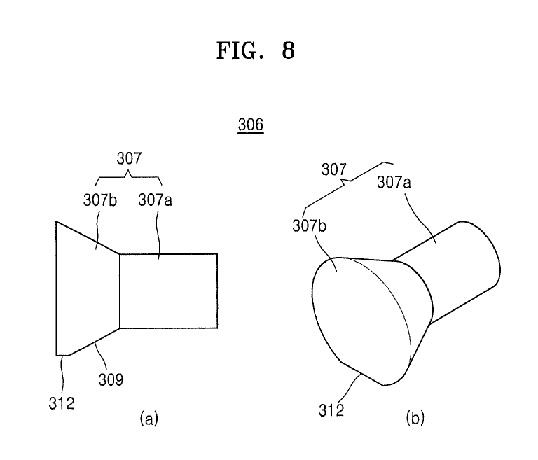

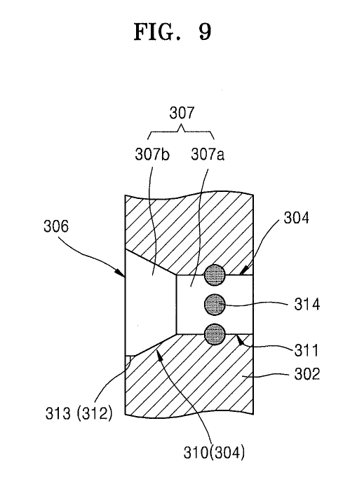

FIG. 5 is an exploded, perspective view illustrating the molding apparatus 820 for semiconductor package fabrication. FIG. 6 is an exploded, perspective view illustrating the air vent holes 304 of the side mold 300 and the air vent controlling member 306 in FIG. 5. FIG. 6 includes a cross-sectional view of a chamber portion 310. FIG. 6 is an enlarged view of a portion VI of FIG. 5. FIGS. 7 and 8 are perspective views illustrating the air vent controlling member 306 of FIG. 6. FIG. 9 is a cross-sectional view illustrating the air vent controlling member 306 mounted in a side mold body 302 of the side mold 300 of FIG. 6.

As shown in FIG. 5, the molding apparatus 820 for semiconductor package fabrication may include the bottom mold 100, the top mold 200, and the side mold 300. The side mold 300 may be located on both sides of the bottom mold 100 and the top mold 200. As described above, the side mold 300 may include the air vent holes 304 which are arranged at regular intervals in the direction (Y direction) perpendicular to the flow direction (X direction) of the molding material 404 of FIG. 1 while having the same size.

The air vent controlling member 306 that is detachable may be mounted in the air vent holes 304. That is, the air vent controlling member 306 that is detachable may be inserted into the air vent holes 304. In such an embodiment, the flow of air discharged through the air vent holes 304 may be controlled.

The air vent controlling member 306 may include an air vent controlling body 307 capable of being inserted into the air vent holes 304, and a sub-air vent hole 308 provided extending through the air vent controlling body 307. As shown in FIGS. 8(a) and 8(b), the air vent controlling member 306 may include only the air vent controlling body 307 without the sub-air vent hole. That is, the air vent controlling member 306 shown in FIGS. 8(a) and 8(b) may be the same as the air vent controlling member 306 of FIG. 7, except that the air vent controlling member 306 shown in FIG. 8 does not include the sub-air vent hole 308.

The air vent controlling member 306 may be inserted into all of the air vent holes 304, or may be inserted into only some of the air vent holes 304. Since the air vent controlling member 306 is inserted into the air vent holes 304 in the flow direction (X direction) of the molding material 404 from the bottom mold 100 and the top mold 200, the air vent controlling member 306 may not deviate from the side mold 300.

The sub-air vent holes 308 in the air vent controlling bodies 307 may have different sizes, as shown in FIGS. 7(a), 7(b), 7(c) and 7(d). A sub-air vent hole 308a, a sub-air vent hole 308b, and a sub-air vent hole 308c shown in FIGS. 7(a), 7(b), and 7(c) respectively have increasing sizes in the stated order. The sub-air vent hole 308 may have a circular, elliptical, or oval shape.

The sub-air vent holes 308a, 308b, 308c shown in FIGS. 7(a), 7(b), and 7(c), respectively, have circular shapes, and may have elliptical shapes, as needed. A sub-air vent hole 308d shown in FIG. 7(d) has an oval shape. When the sub-air vent hole 308d has an oval shape, as in FIG. 7(d), even though the molding object on the bottom mold 100 is warped, the sub-air vent hole 308d may not be blocked since the sub-air vent hole 308d has the oval shape that is long in an up-and-down direction.

As shown in FIGS. 6 and 9, the air vent hole 304 may include a chamber portion 310 having an inclined inner side. That is, the chamber portion 310 may be wider at a first outer edge of the side mold body 302 and may be inclined such that the opening of the chamber portion 310 becomes smaller in a direction towards an inner portion of the side mold body 302. The air vent hole 304 may include a cylindrical body 311 extending from the chamber portion 310 to a second outer edge of the side mold body 302 opposite the first outer edge of the side mold body 302. The chamber portion 310 may include a flat portion 313 along a lower portion of the chamber portion 310. The chamber portion 310 extends from the flat portion 313 at an incline. The air vent controlling body 307 may include a cylindrical body 307a inserted into the air vent hole 304, and a tap-type body 307b capable of being inserted into the chamber portion 310. The tap-type body 307b may include an inclined portion 309 inserted into the chamber portion 310 of the air vent hole 304. As shown in FIG. 7(a), the tap-type body 307b may include a flat portion 312 directing the direction and shape of the air vent controlling member 306 when the air vent controlling member 306 is inserted into the air vent hole 304. The flat portion 312 may be aligned with the flat portion 313 of chamber portion 310 when the air vent controlling member 306 is inserted into the air vent hole 304.

As shown in FIG. 9, the air vent controlling member 306 may be inserted into the air vent hole 304 in the side mold body 302 of the side mold 300. A locking member 314 for fastening the air vent controlling member 306 to the air vent hole 304 may be provided around the cylindrical body 307a of the air vent controlling member 306. The locking member 314 is provided in order to tightly lock the air vent controlling member 306 to the air vent hole 304. The locking member 314 may not be provided, as needed.

As described above, the molding apparatus 820 for semiconductor package fabrication may include the air vent controlling member 306 inserted into the air vent hole 304 of the side mold 300. Thus, the molding apparatus 820 for semiconductor package fabrication can more uniformly control flow of the molding material 404 by more finely controlling flow of air that is discharged through the air vent holes 304.

In addition, in the molding apparatus 820 for semiconductor package fabrication, in order to optimize the molding process, based on a kind or type of molding object 500 and properties of the molding material 404, the air vent controlling member 306 may not be inserted into the air vent holes 304, or a size of the sub-air vent hole 308 of the air vent controlling member 306 inserted into the air vent holes 304 may be adjusted.

Therefore, in the molding apparatus 820 for semiconductor package fabrication, since the bottom mold 100, the top mold 200, and the side mold 300 do not need to be repeatedly manufactured based on a type of molding object 500 and properties of the molding material 404, fabrication costs of a semiconductor package can be greatly reduced.

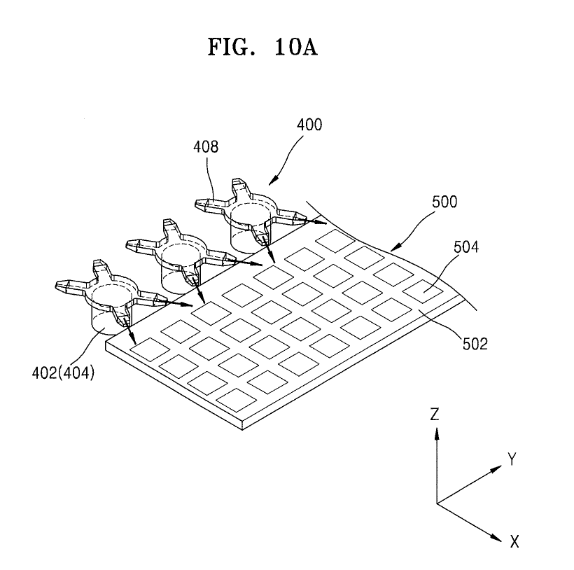

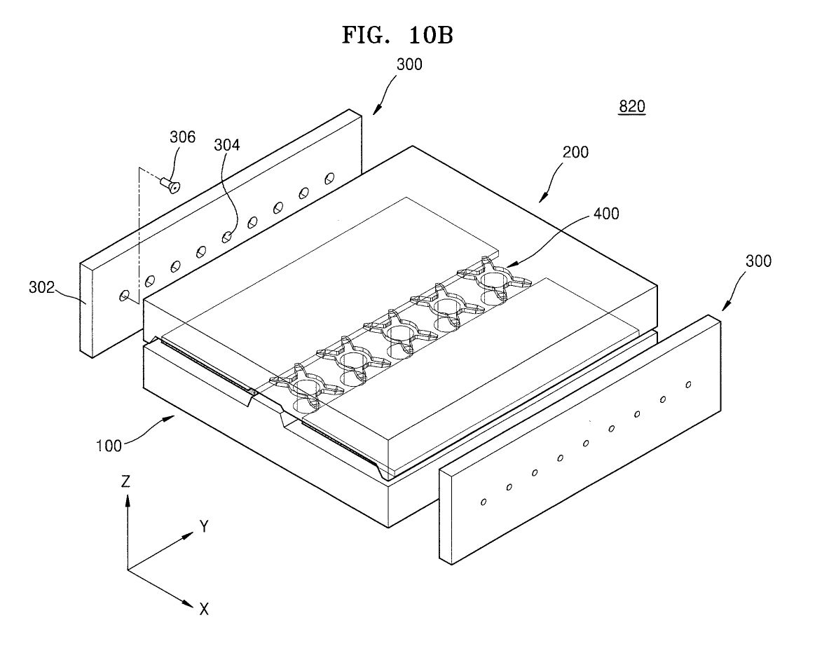

FIGS. 10A and 10B are diagrams illustrating a molding process using the molding apparatus for semiconductor package fabrication of FIGS. 5 to 9.

Specifically, in FIGS. 10A and 10B, the same reference numerals as in FIGS. 5 to 9 may denote the same components as in FIGS. 5 to 9, and the same components will be briefly described or omitted for convenience.

FIG. 10B is an exploded, perspective view illustrating the molding apparatus 820 for semiconductor package fabrication including the molding material supplier 400, and FIG. 10A is an exploded, perspective view illustrating the molding material supplier 400 and the molding object 500. FIG. 10A illustrates the molding object 500 only at one side of the molding apparatus 820.

As shown in FIG. 10B, the molding material supplier 400 may be located in the central portion of the bottom mold 100. As described above and as illustrated in FIG. 10A, the molding material supplier 400 may include the molding material 404, the plunger 402 capable of pressing the molding material 404, and the molding material flow path 408, for example, a runner or a gate, through which the molding material 404 flows. As described above, the molding object 500 may include the plurality of semiconductor chips 504 on the printed circuit board 502.

The molding material 404 may be heated by a heating means (not shown). The heated molding material 404 may be fluidized and be pressed by the plunger 402, whereby the molding material 404 may pass through the molding material flow path 408 and flow onto the molding object 500, as denoted by arrows extending from the flow path 408. Air flow may be more finely controlled using the air vent hole 304 of the side mold 300 and the air vent controlling member 306 mounted thereto. The molding apparatus 820 for semiconductor package fabrication may uniformly control flow of the molding material 404 which flows onto the molding object 500.

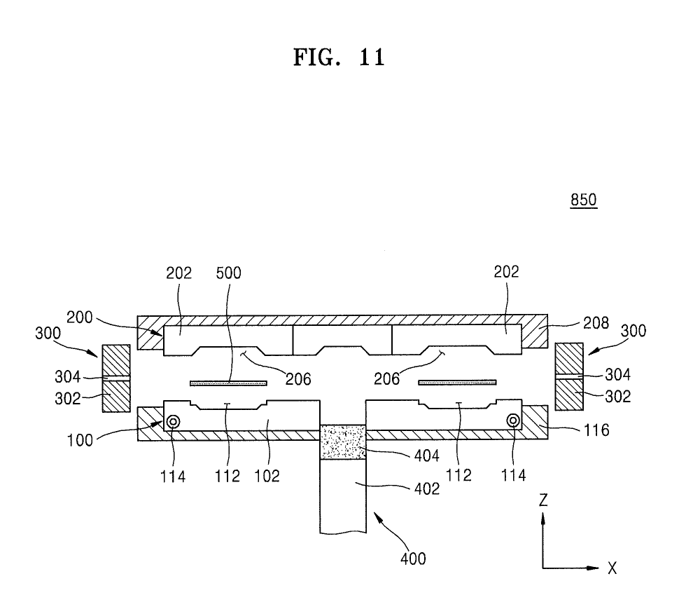

FIG. 11 is an exploded, cross-sectional view illustrating a molding apparatus for semiconductor package fabrication according to some embodiments of the present inventive concepts.

Specifically, a molding apparatus 850 for semiconductor package fabrication may be substantially similar to the molding apparatus 800 for semiconductor package fabrication of FIGS. 1 to 4, except that the molding apparatus 850 for semiconductor package fabrication includes a bottom cavity 112 and a top cavity 206. In FIG. 11, the same reference numerals as in FIGS. 1 to 4 may denote the same components as in FIGS. 1 to 4, and the same components will be briefly described or omitted for convenience.

FIG. 11 is an exploded, cross-sectional view of the molding apparatus 850 for semiconductor package fabrication. The molding apparatus 850 for semiconductor package fabrication may include the bottom mold 100, the top mold 200, the side mold 300, and the molding material supplier 400. The bottom mold 100 may include the bottom mold body 102. A lower surface of the bottom mold body 102 may be supported by a bottom mold supporter 116. When the molding apparatus 850 for semiconductor package fabrication includes the bottom mold supporter 116, the molding process may be more stably performed.

The bottom cavity 112, in which the molding object 500 can be mounted, may be provided on the upper surface of the bottom mold body 102. The bottom cavity 112 may have a step, as needed, and thus, a lower surface of the molding object 500 may also be molded. That is, molding material 404 may be provided on a lower surface of the molding object 500. The bottom mold body 102 may include a heater 114 capable of heating the molding material 404.

The molding material supplier 400 capable of injecting the molding material 404 may be provided in the central portion of the bottom mold 100. The molding material supplier 400 may include the molding material 404 and the plunger 402 capable of pressing the molding material 404.

The top mold 200 includes the top mold body 202. The top cavity 206, into which the molding material 404 can be injected, may be provided on the lower surface of the top mold body 202. An upper surface of the top mold body 202 may be supported by a top mold supporter 208. When the molding apparatus 850 for semiconductor package fabrication includes the top mold supporter 208, the molding process maybe more stably performed.

The side mold 300 having the plurality of air vent holes 304 may be located on both sides of the bottom mold 100 and the top mold 200. As such, the molding apparatus 850 for semiconductor package fabrication can uniformly control flow of the molding material 404 by finely controlling a flow of air that flows through the air vent holes 304.

In addition, the molding apparatus 850 for semiconductor package fabrication includes the bottom cavity 112 and the top cavity 206, thereby realizing molding layers having various shapes. For example, the bottom cavity 112 has a step, such that a molding layer may also be formed on the lower surface of the molding object 500.

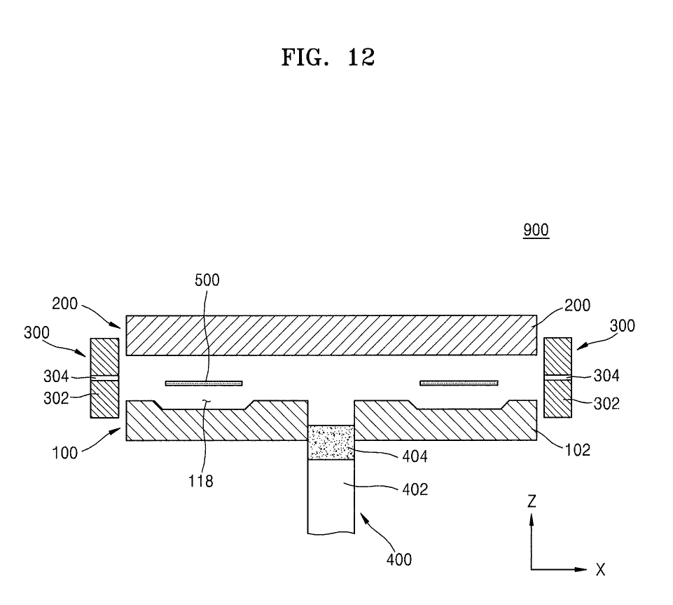

FIG. 12 is an exploded, cross-sectional view illustrating a molding apparatus for semiconductor package fabrication according to some embodiments of the present inventive concepts.

Specifically, a molding apparatus 900 for semiconductor package fabrication may be substantially similar the molding apparatus 800 for semiconductor package fabrication of FIGS. 1 to 4, except that the molding apparatus 900 for semiconductor package fabrication does not include the top cavity, for example, top cavity 204 of FIG. 1. In FIG. 12, the same reference numerals as in FIGS. 1 to 4 may denote the same components as the components in FIGS. 1 to 4, and the same components will be briefly described or omitted for convenience.

FIG. 12 is an exploded, cross-sectional view of the molding apparatus 900 for semiconductor package fabrication. The molding apparatus 900 for semiconductor package fabrication may include the bottom mold 100, the top mold 200, the side mold 300, and the molding material supplier 400. The bottom mold 100 may include the bottom mold body 102.

A bottom cavity 118, in which the molding object 500 can be mounted, may be provided on the surface of the bottom mold body 102. The molding material supplier 400 capable of injecting the molding material 404 may be provided in the central portion of the bottom mold 100. The bottom cavity 118 may be provided on both sides of the molding material supplier 400. The molding material supplier 400 may include the molding material 404 and the plunger 402 capable of pressing the molding material 404.

The top mold 200 includes the top mold body 202. The top cavity, for example, top cavity 204 in FIG. 1, is not provided on the surface of the top mold body 202. The side mold 300 having the air vent holes 304 may be located on both sides of the bottom mold 100 and the top mold 200.

As such, the molding apparatus 900 for semiconductor package fabrication can uniformly control flow of the molding material 404 by finely controlling flow of air that flows through the air vent holes 304. In addition, since the molding apparatus 900 for semiconductor package fabrication does not include the top cavity, for example, top cavity 204 in FIG. 1, if a step height of the bottom cavity 118 is low, a molding layer may be formed only on both side surfaces and the lower surface of the molding object 500 while a molding layer may not be formed on an upper surface of the molding object 500.

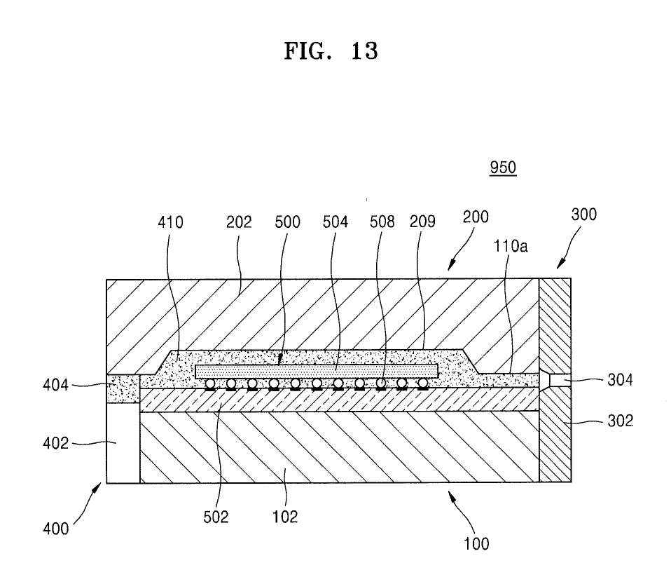

FIG. 13 is a cross-sectional view illustrating a molding apparatus 950 for semiconductor package fabrication according to some embodiments of the present inventive concepts.

Specifically, the molding apparatus 950 for semiconductor package fabrication may be substantially similar to the molding apparatus 800 for semiconductor package fabrication of FIGS. 1 to 4, except that the molding material supplier 400 is located on one side of the bottom mold 100, that a top cavity 209 has a different shape than top cavity 204 of FIG. 1, and that an air flow path 110a has a longer length than air flow path 110 of FIG. 1.

FIG. 13 additionally shows a molding layer 410 formed on the molding object 500 by using the molding apparatus 950 for semiconductor package fabrication. The molding object 500 of FIG. 13 is described using one semiconductor chip 504 for convenience. In FIG. 13, the same reference numerals as in FIGS. 1 to 4 may denote the same components as in FIGS. 1 to 4, and the same components will be briefly described or omitted for convenience.

The molding apparatus 950 for semiconductor package fabrication may include the bottom mold 100, the top mold 200, the side mold 300, and the molding material supplier 400. The bottom mold 100 may include the bottom mold body 102. The bottom cavity is not provided on the surface of the bottom mold body 102 in FIG. 13, and the molding object 500 is mounted on the upper surface of the bottom mold body 102. The molding object 500 may include the printed circuit board 502, and the semiconductor chip 504 connected onto the printed circuit board 502 using a connection bump 508. The printed circuit board 502 contacts the upper surface of the bottom mold body 102.

The molding material supplier 400 capable of injecting the molding material 404 between the top mold 200 and the bottom mold 100 may be provided on one side of the bottom mold 100. The molding material supplier 400 may include the molding material 404 and the plunger 402 capable of pressing the molding material 404.

The top mold 200 includes the top mold body 202. The top cavity 209 is provided on a lower surface of the top mold body 202. The side mold 300 having the air vent holes 304 may be located on both sides of the bottom mold 100 and the top mold 200. Alternatively, as illustrated in FIG. 13, the side mold 300 having the air vents 304 may be located on one side of the bottom mold 100 and the top mold 200, for example, on the side opposite to the side on which the molding material supplier 400 is formed.

As such, the molding apparatus 950 for semiconductor package fabrication may uniformly control flow of the molding material 404 by finely controlling flow of air that flows through the air vent holes 304.

In addition, in the molding apparatus 950 for semiconductor package fabrication, the top cavity 209 includes the air flow path 110a having a length that is longer than that of the air flow path 110 of FIG. 1. In this way, during the molding process, flow of the molding material 404 between the top mold 200 and the bottom mold 100 is good, and air can be easily discharged into the air vent holes 304 of the side mold 300.

Further, the molding apparatus 950 for semiconductor package fabrication includes the long air flow path 110a, while not including the bottom cavity. As a result, the molding layer 410 may be formed, while the molding material 404 easily fills spaces between the connection bumps 508.

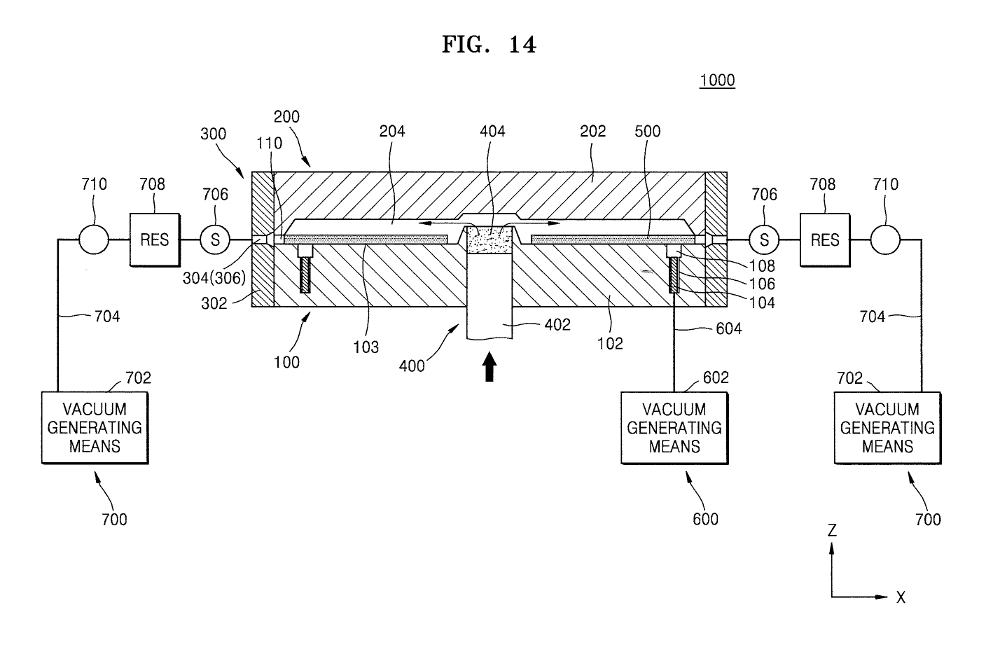

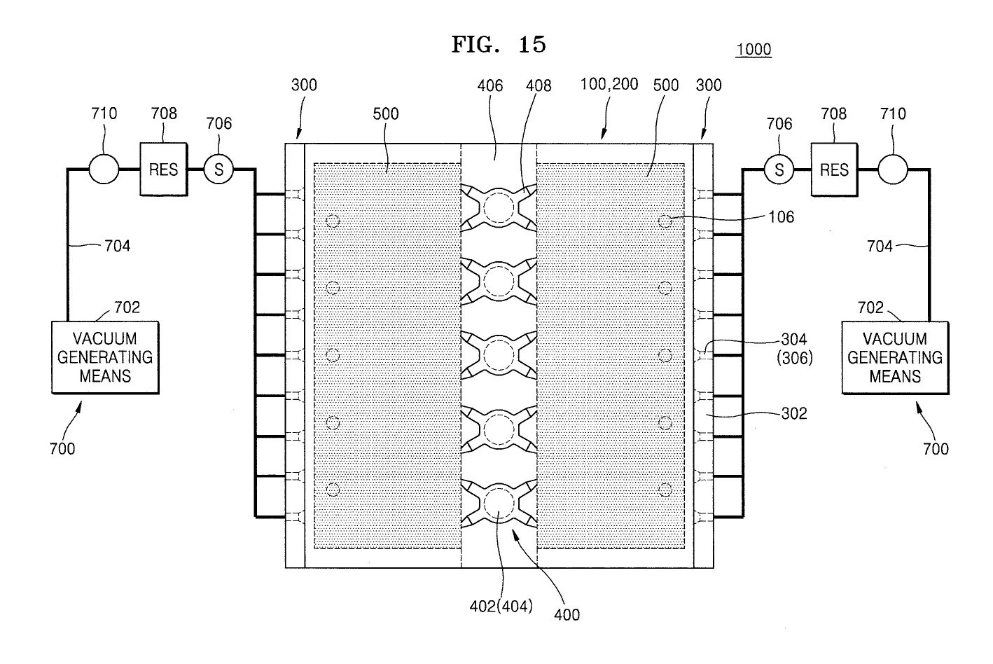

FIGS. 14 and 15 are diagrams illustrating a molding apparatus for semiconductor package fabrication according to some embodiments of the present inventive concepts.

Specifically, a molding apparatus 1000 for semiconductor package fabrication of FIGS. 14 and 15 may be substantially similar to the molding apparatuses 800 and 820 for semiconductor package fabrication of FIGS. 1 to 9, except that the molding apparatus 1000 for semiconductor package fabrication includes an air reservoir 708 and an additional air vent controlling member 306.

In FIGS. 14 and 15, the same reference numerals as in FIGS. 1 to 9 may denote the same components as in FIGS. 1 to 9, and the same components will be briefly described or omitted for convenience. FIG. 14 is a cross-sectional view of the molding apparatus 1000 for semiconductor package fabrication, and FIG. 15 is a plan view of the molding apparatus 1000 for semiconductor package fabrication.

The molding apparatus 1000 for semiconductor package fabrication may include the bottom mold 100, the top mold 200, and the side mold 300. The side mold 300 may be located on both sides of the bottom mold 100 and the top mold 200. As described above, the side mold 300 may include the air vent holes 304 which are arranged at regular intervals in the direction (Y direction) perpendicular to the flow direction (X direction) of the molding material 404 while having the same size.

As shown in FIG. 5, the air vent controlling member 306 that is detachable may be provided in the air vent holes 304. That is, the air vent controlling member 306 that is detachable may be inserted into the air vent holes 304. In this case, flow of air discharged through the air vent holes 304 may be controlled. The air vent controlling member 306 may be provided, as needed. Since the air vent controlling member 306 has been described above, descriptions thereof will be omitted.

An air sucking unit 700 may be connected to the air vent holes 304 of the side mold 300. The air sucking unit 700 may include an exhaust pipe 704 connected to the air vent holes 304 and a vacuum generating means 702 connected to the exhaust pipe 704. The molding apparatus 1000 for semiconductor package fabrication may include the air reservoir 708 provided to the exhaust pipe 704. The air reservoir 708 may be formed along the exhaust pipe 704 between the side mold 300 and the vacuum generating means 702. The air reservoir 708 may serve to allow air flow in the exhaust pipe 704 to be uniform, and may serve to control a pressure around the air vent holes 304.

The additional air vent controlling member 710 that is detachable may be provided to the exhaust pipe 704 at a front or rear end of the air reservoir 708. The additional air vent controlling member 710 may be formed between the side mold 300 and the air reservoir 708 or between the air reservoir 708 and the vacuum generating means 702. The additional air vent controlling member 710 may have the same shape, or substantially the same shape, as the air vent controlling member 306 described above with reference to FIGS. 5 to 8.

The additional air vent controlling member 710 may include an additional sub-air vent hole as described above with reference to FIGS. 5 to 8. The exhaust pipe 704 may have a cylindrical shape, and the air vent controlling member 306 described above with reference to FIGS. 5 to 8 may be easily provided to the exhaust pipe 704. Thus, flow of air that flows through the exhaust pipe 704 may be easily controlled.

The exhaust pipe 704 may include a sensor 706 sensing an air flow rate. The sensor 706 may be located between the side mold 300 and the air reservoir 708. In FIGS. 14 and 15, although the sensor 706 is provided to the front end of the air reservoir 708, and the additional air vent controlling member 710 is provided to the exhaust pipe 704 at the rear end of the air reservoir 708, this configuration is shown for convenience and the present inventive concepts are not limited thereto.

In the molding apparatus 1000 for semiconductor package fabrication, the air reservoir 708 and the additional air vent controlling member 710 may be provided to the exhaust pipe 704. Therefore, the molding apparatus 1000 for semiconductor package fabrication can uniformly control flow of the molding material 404 by finely controlling flow of air that flows through the air vent holes 304.

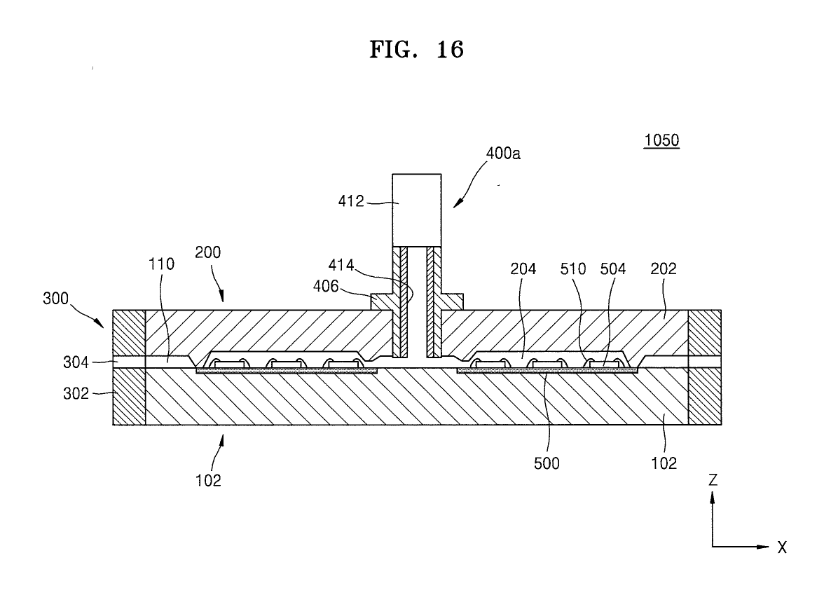

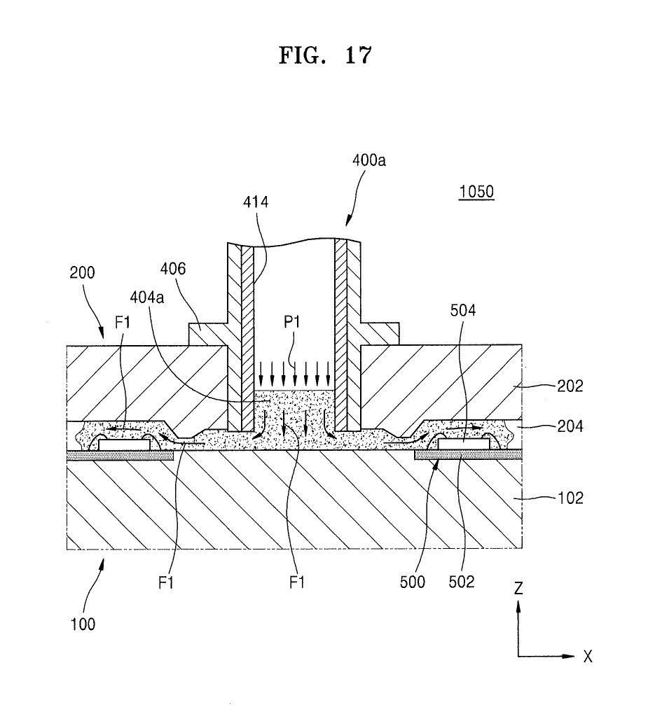

FIGS. 16 and 17 are diagrams illustrating a molding apparatus for semiconductor package fabrication according to some embodiments of the present inventive concepts.

Specifically, a molding apparatus 1050 for semiconductor package fabrication may be similar to the molding apparatus 800 for semiconductor package fabrication of FIGS. 1 to 4, except that a molding material supplier 400a of FIGS. 16 and 17 is provided in the central portion of the top mold 200 rather than the central portion of the bottom mold 100 as in FIGS. 1 to 4.

In FIGS. 16 and 17, the same reference numerals as in FIGS. 1 to 4 may denote the same components as in FIGS. 1 to 4, and the same components will be briefly described or omitted for convenience. FIG. 16 is a cross-sectional view of the molding apparatus 1050 for semiconductor package fabrication, and FIG. 17 is a cross-sectional view illustrating injection of a molding material 404a into the cavity 204 of FIG. 16.

The molding apparatus 1050 for semiconductor package fabrication may include the bottom mold 100, the top mold 200, the side mold 300, and the molding material supplier 400a. The bottom mold 100 includes the bottom mold body 102. The molding object 500 is mounted on the bottom mold body 102. The molding object 500 may include the printed circuit board 502, and the semiconductor chip 504 connected to the printed circuit board 502 by a bonding wire 510. The molding object 500 may be positioned on both sides of the molding material supplier 400a.

The top mold 200 includes the top mold body 202. The top cavity 204 is provided on the lower surface of the top mold body 202. The molding material supplier 400a capable of supplying the molding material 404a may be provided in the central portion of the top mold 200. The molding material supplier 400a may include a fluidic molding material supplying block 406, a non-adhesive coating layer 414, and a fluidic molding material injecting device 412. The fluidic molding material supplying block 406 may extend along a portion of the upper surface of the top mold body 202.

The non-adhesive coating layer 414 may be formed on an inner wall of the fluidic molding material supplying block 406 such that a fluidic molding material does not remain on the inner wall of the fluidic molding material supplying block 406. The non-adhesive coating layer 414 may include various coating layers, such as organic materials including, for example, silicon compounds, Teflon compounds, and the like; inorganic materials including, for example, carbon compounds, diamond compounds, and the like; waterproof/water-repellent coatings and nano-coatings, which increase surface tension, and the like.

The molding material supplier 400a may be a unit which supplies the fluidic molding material 404a using the fluidic molding material injecting device 412. As shown in FIG. 17, the molding material supplier 400a may allow the fluidic molding material 404a to flow into the top cavity 204 by applying a pressure to the fluidic molding material 404a in a direction denoted by arrows P1.

That is, as shown in FIG. 17, the fluidic molding material 404a supplied by the molding material supplier 400a may easily flow on upper sides of the printed circuit board 502 and the semiconductor chip 504, which constitute the molding object 500, through the top cavity 204, as denoted by arrows F1.

The side mold 300 having the air vent holes 304 may be located on both sides of the bottom mold 100 and the top mold 200. When the side mold 300 includes the air vent holes 304, flow of the molding material 404a may be uniformly controlled by finely controlling flow of air that flows through the air vent holes 304. Air vent controlling members 306 may be inserted in air vent holes 304. Therefore, the molding apparatus 1050 for semiconductor package fabrication may facilitate molding of the molding object 500 even though the molding material supplier 400a is included in the central portion of the top mold 200.

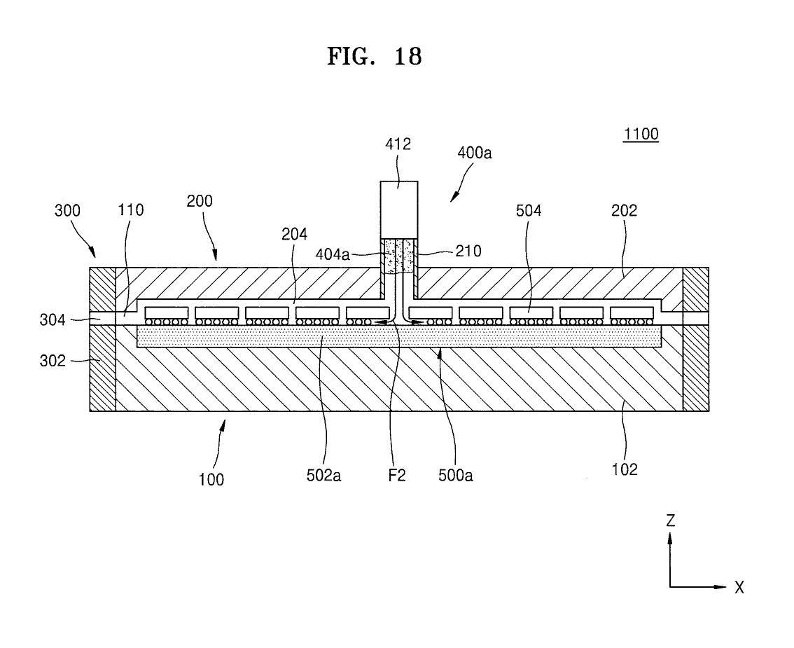

FIGS. 18 to 20 are diagrams illustrating a molding apparatus for semiconductor package fabrication according to some embodiments of the present inventive concepts.

Specifically, a molding apparatus 1100 for semiconductor package fabrication may be substantially similar to the molding apparatus 800 for semiconductor package fabrication of FIGS. 1 to 4, except that the molding material supplier 400a is provided in the central portion of the top mold 200, and that a molding object 500a includes a wafer-shaped carrier substrate 502a.

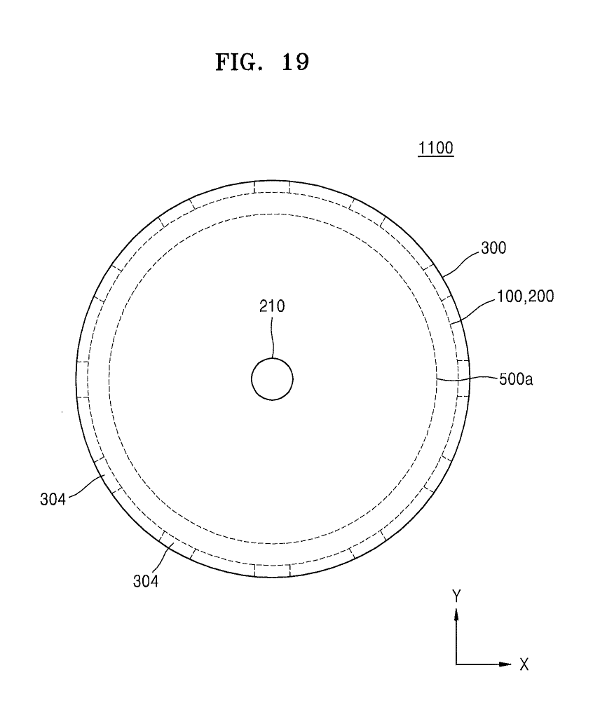

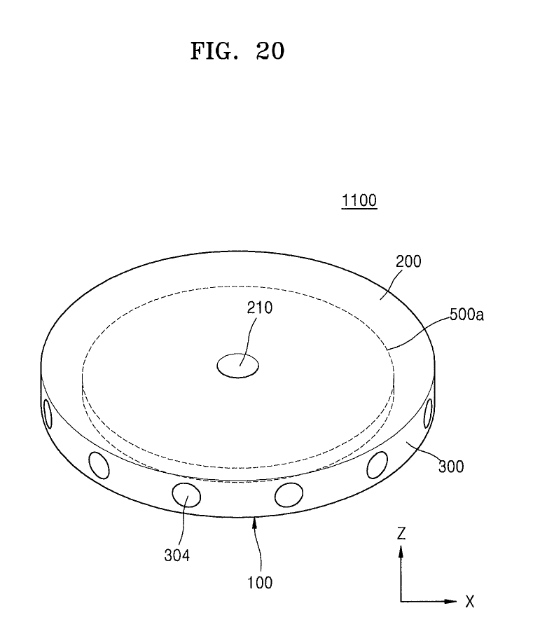

In FIGS. 18 to 20, the same reference numerals as in FIGS. 1 to 4 may denote the same components as in FIGS. 1 to 4, and the same components will be briefly described or omitted for convenience. FIG. 18 is a cross-sectional view of the molding apparatus 1100 for semiconductor package fabrication, FIG. 19 is a plan view of the molding apparatus 1100 for semiconductor package fabrication, and FIG. 20 is a perspective view of the molding apparatus 1100 for semiconductor package fabrication.

The molding apparatus 1100 for semiconductor package fabrication may include the bottom mold 100, the top mold 200, the side mold 300, and the molding material supplier 400a located at a central portion of the top mold 200. The bottom mold 100 includes the bottom mold body 102. The molding object 500 is mounted on the bottom mold body 102. The molding object 500 may include the carrier substrate 502a shaped like a wafer, and the semiconductor chip 504 which is mounted on the carrier substrate 502a and has the connection bumps 508. The carrier substrate 502a may have a circular wafer shape. The semiconductor chips may be mounted on the carrier substrate 502a on both sides of the molding material supplier 400a. The carrier substrate 502a may include, for example, a silicon, germanium, silicon geinlanium, gallium arsenide (GaAs), glass, metal, plastic, ceramic substrate, or the like.

The top mold 200 includes the top mold body 202. The top cavity 204 is provided on the lower surface of the top mold body 202. The molding material supplier 400a capable of supplying the molding material 404a through an injection port 210 may be provided in the central portion of the top mold 200. The molding material supplier 400a may include, for example, the fluidic molding material injecting device 412.

The molding material supplier 400a may be a unit which supplies the fluidic molding material 404a using the fluidic molding material injecting device 412. As shown in FIG. 18, the molding material supplier 400a may allow the fluidic molding material 404a to flow into the top cavity 204, as denoted by arrows P2. As shown in FIG. 18, the fluidic molding material 404a supplied by the molding material supplier 400a may flow through the top cavity 204 to seal the molding object 500 including the carrier substrate 502a and the semiconductor chip 504.

The top mold 200 and the bottom mold 100 may have a circular shape. That is, the top mold 200 and the bottom mold 100 may have the same shape as the carrier substrate 502a. The side mold 300 having the air vent holes 304 may be located around the bottom mold 100 and the top mold 200. That is, the side mold 300 may surround the circular top mold 200 and the circular bottom mold 100. Air vent controlling members 306 may be inserted in air vent holes 304. When the side mold 300 includes the air vent holes 304, uniform flow of the molding material 404a can be obtained by finely controlling flow of air that flows through the air vent holes 304, thereby facilitating molding of the molding object 500a.

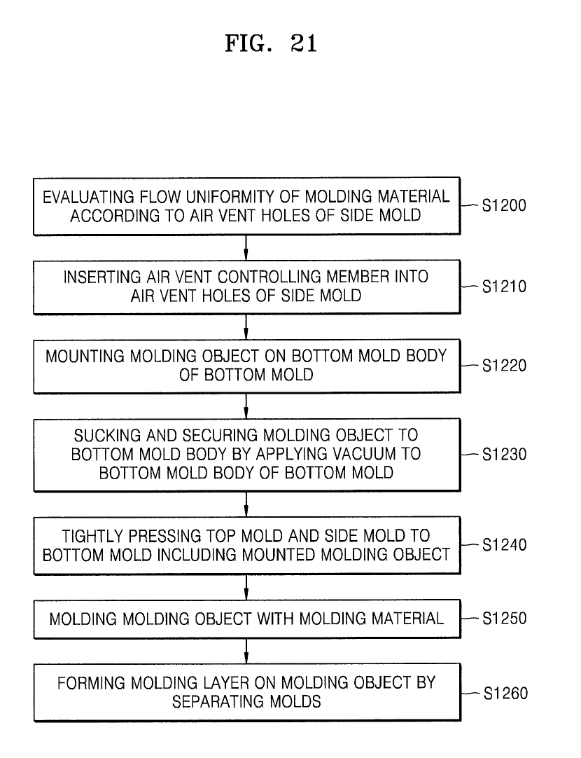

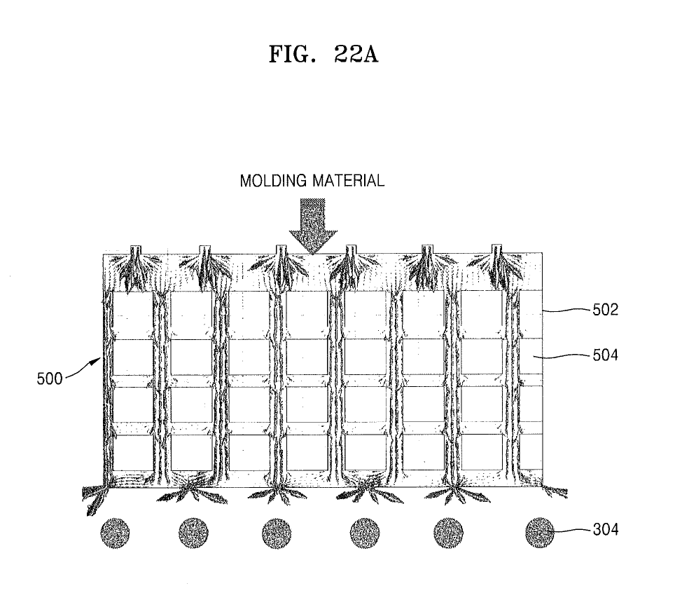

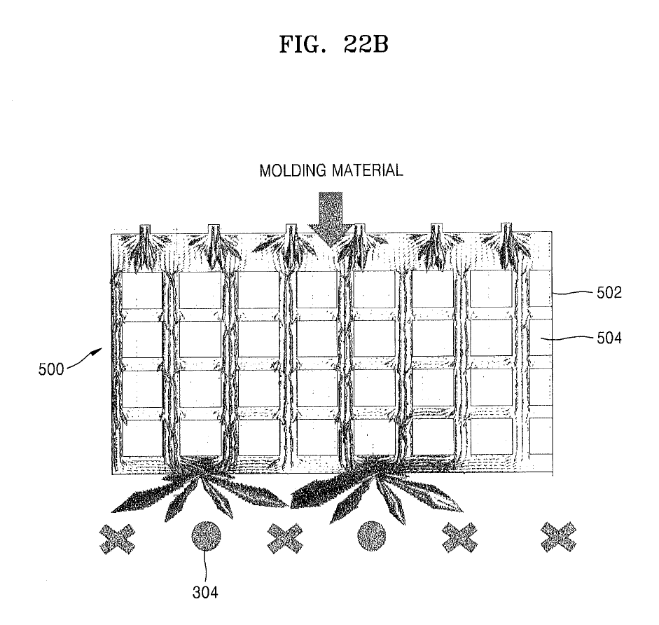

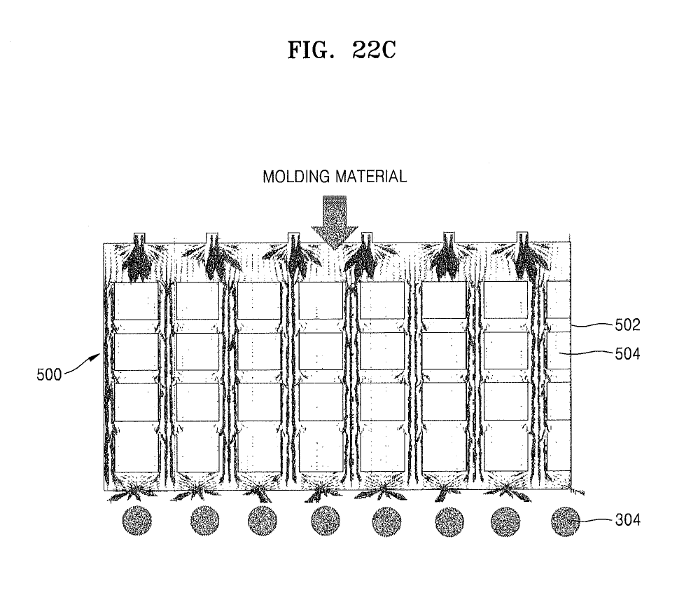

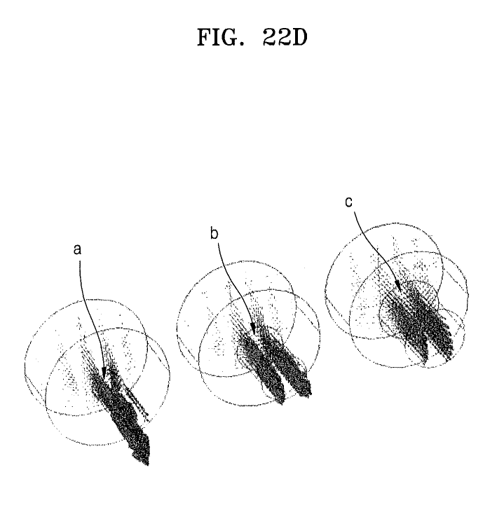

FIG. 21 is a flowchart of a method of molding a semiconductor package according to some embodiments of the present inventive concepts, and FIGS. 22A to 22D are diagrams illustrating simulation results obtained by evaluating flow uniformity of a molding material depending upon air vent holes of a side mold of FIG. 21.

Specifically, the method of molding the semiconductor package may be described with reference to FIGS. 1 to 9. The method of molding the semiconductor package includes evaluating flow uniformity of the molding material 404 of FIGS. 1 to 9 depending upon the air vent holes 304 of FIGS. 1 to 9 included in the side mold 300 of FIGS. 1 to 9 (S1200).

The evaluation of the flow uniformity of the molding material 404 depending upon the air vent holes 304 may include evaluating the flow of the molding material 404 flowing on the molding object 500 based on properties of the molding material 404 using a simulation. The properties of the molding material 404 may include, for example, viscosity of the molding material 404, and the like, depending upon a type or kind of the molding material 404. The molding object 500 may include the printed circuit board 502 and the semiconductor chip 504.

The evaluation of the flow uniformity of the molding material 404 based on the air vent holes 304 may include, for example, evaluating the flow of the molding material 404 based on a type of the molding object 500, an arrangement of the air vent holes 304 with respect to the molding object 500, or the sizes of the air vent holes 304 through a simulation.

As shown in FIGS. 22A to 22C, the evaluation of the flow uniformity of the molding material 404 based on the air vent holes 304 may include evaluating the flow uniformity of the molding material 404 based on an arrangement of the air vent holes 304 with respect to the molding object 500.

As shown in FIG. 22A, when the air vent holes 304 are arranged on one side of the molding object 500 at regular intervals, the flow uniformity of the molding material is relatively good. In contrast, as shown in FIG. 22B, when the air vent holes 304 are arranged on one side of the molding object 500 at irregular intervals, the flow uniformity of the molding material is poor. In addition, as shown in FIG. 22C, when the air vent holes 304 are arranged on one side of the molding object 500 at more regular intervals so as to correspond to the semiconductor chips 504, the flow uniformity of the molding material may be improved.

The evaluation of the flow uniformity of the molding material 404 based on the air vent holes 304 may include evaluating the flow uniformity based on diameters of the air vent holes 304 through a simulation. As shown in FIG. 22D, in the evaluation of the flow uniformity of the molding material 404 based on the air vent holes 304, a flow rate of the molding material 404 may be high when the diameters of the air vent holes are smaller, and the flow rate of the molding material 404 may be low when the diameters of the air vent holes are larger.

The air vent controlling member 306 is inserted into each of the air vent holes 304 of the side mold 300 (S1210). The air vent controlling member 306 may include the sub-air vent hole 308 of FIGS. 1 to 9. The insertion of the air vent controlling member 306 into each of the air vent holes 304 may include inserting the air vent controlling member 306 having the sub-air vent hole 308 of a different size into each of the air vent holes 304 according to an evaluation result of the flow uniformity of the molding material 404. As described above, the air vent controlling members 306 may not include the sub-air vent hole 308, or may include the sub-air vent holes 308 having different sizes, for example, diameters.

The molding object 500 is mounted on the bottom mold 100 of FIGS. 1 to 9 (S 1220). The molding object 500 may include the semiconductor chip 504 on the printed circuit board 502 of FIGS. 1 to 9. The molding object 500 may be sucked on to and secured to the bottom mold body 102 by applying a vacuum to the bottom mold body 102 of the bottom mold 100 including the molding object 500 (S1230) by using, for example, vacuum generating means 600 and 700.

The top mold 200 of FIGS. 1 to 9 and the side mold 300 of FIGS. 1 to 9 are tightly pressed to the bottom mold 100 including the molding object 500 that is mounted thereon (S1240). A molding process is performed by supplying the molding material 404 to the molding object 500 in the bottom mold 100, the top mold 200, and the side mold 300, which are tightly pressed to each other (S1250).

That is, the molding object 500 located between the bottom mold 100, the top mold 200, and the side mold 300 is molded with the molding material 404. The molding material 404 may be, for example, an epoxy resin. During the molding process, air flow can be controlled using the air vent holes 304. In addition, during the molding process, uniform flow of the molding material 404 may be obtained by controlling air flow using the sub-air vent holes 308 in the air vent controlling members 306. Thus, the molding material 404 may sufficiently fill an internal space formed by the bottom mold 100, the top mold 200, and the side mold 300.

A molding layer is formed on the molding object 500 by separating the bottom mold 100, the top mold 200, and the side mold 300 from each other (S1260). As described above, since the molding material 404 sufficiently fills the internal space formed by the bottom mold 100, the top mold 200, and the side mold 300, occurrence of defects such as voids in the molding layer may be suppressed.

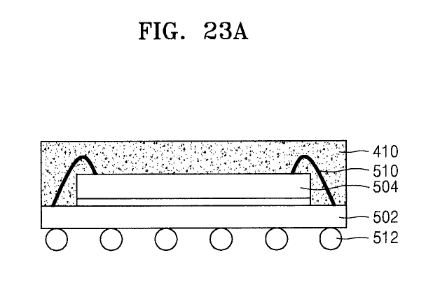

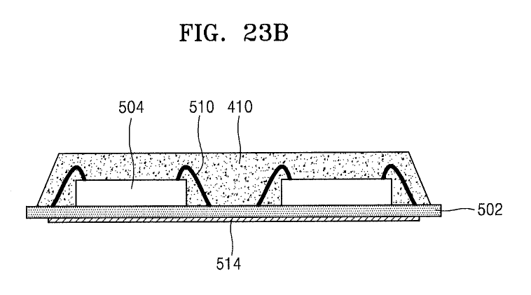

FIGS. 23A and 23B are cross-sectional views illustrating semiconductor packages fabricated using a molding apparatus for semiconductor package fabrication according to some embodiments of the present inventive concepts.

Specifically, in the semiconductor packages shown in FIGS. 23A and 23B, the semiconductor chip 504 is attached onto the printed circuit board 502, and electrically connected to the printed circuit board 502 via the bonding wire 510. The semiconductor packages include the semiconductor chip 504 and the bonding wire 510, and the printed circuit board 502 is molded by using the molding layer 410. The molding layer 410 is formed covering the bonding wires 510, the top and sidewalls of the semiconductor chips 504 and the exposed upper surface of the printed circuit board 502.

On a lower side of the printed circuit board 502 of FIG. 23A, a solder ball 512 is formed as an external connection terminal. As illustrated in FIG. 23B, the plurality of semiconductor chips 504 may be located on the printed circuit board 502. An external connection conductive pad 514 may be located on the lower side of the printed circuit board 502 of FIG. 23B.

As such, the semiconductor package fabricated by the molding apparatus for semiconductor package fabrication according to the inventive concepts may include the semiconductor chip 504 electrically connected to the printed circuit board 502 using the bonding wire 510, and the molding layer 410 molding the components set forth above.

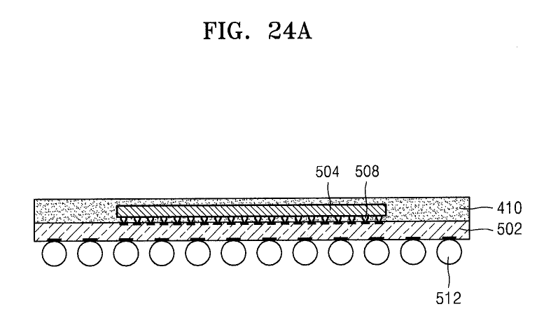

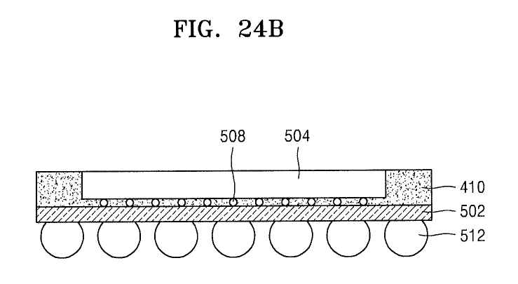

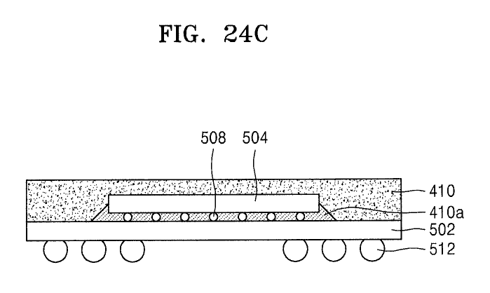

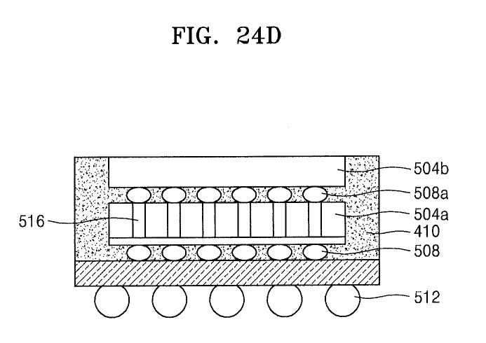

FIGS. 24A to 24D are cross-sectional views illustrating semiconductor packages fabricated using a molding apparatus for semiconductor package fabrication according to some embodiments of the present inventive concepts.

Specifically, the semiconductor packages shown in FIGS. 24A to 24D include the semiconductor chip 504 electrically connected to the printed circuit board 502 via the connection bumps 508. The semiconductor packages include the semiconductor chip 504 and the connection bumps 508, and the printed circuit board 502 is molded with the molding layer 410. In FIG. 24A, the molding layer 410 covers the semiconductor chip 504, connection bumps 508 and exposed portions of the uppers surface of the printed circuit board 502.

On the lower side of the printed circuit board 502 of FIGS. 24A to 24D, the solder ball 512 is formed as an external connection terminal. An upper surface of the semiconductor chip 504 of FIG. 24B may be exposed to the outside of the semiconductor package. That is, in FIG. 24B, the molding layer 410 is not formed on the upper surface of the semiconductor chip 504. In FIG. 24C, an under-fill layer 410a may be formed on the printed circuit board 502 under the semiconductor chip 504. The under-fill layer 410a may also be formed by the molding apparatus for semiconductor package fabrication according to the inventive concepts. In the semiconductor package of FIG. 24D, a plurality of semiconductor chips 504a, 504b are stacked on the printed circuit board 502, the plurality of semiconductor chips 504a, 504b may be electrically connected to each other using a through-via 516 and internal connection bumps 508a.

As such, the semiconductor package fabricated by the molding apparatus for semiconductor package fabrication according to the inventive concepts may include the semiconductor chip 504 electrically connected to the printed circuit board 502 using the connection bumps 508, and the molding layer 410 molding the components set forth above.

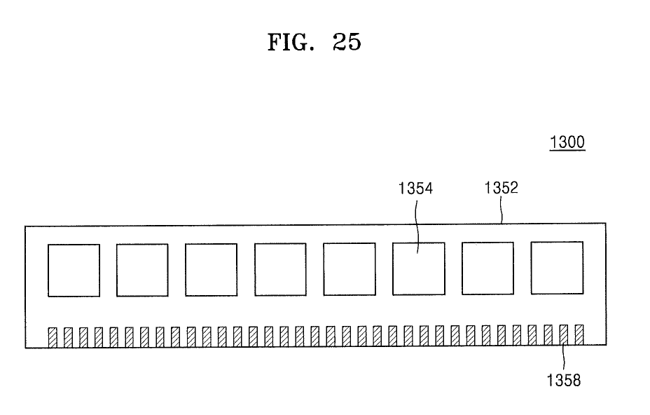

FIG. 25 is a schematic, plan view of a semiconductor module including a semiconductor package according to some embodiments of the present inventive concepts.

Specifically, a semiconductor module 1300 includes a module substrate 1352, a plurality of semiconductor packages 1354 on the module substrate 1352, and module contact terminals 1358. The module contact terminals 1358 are formed side by side at one edge of the module substrate 1352 and each of the module contact terminals 1358 is electrically connected to the semiconductor packages 1354.

The module substrate 1352 may be a printed circuit board (PCB). Both surfaces of the module substrate 1352 may be used. That is, the semiconductor packages 1354 may be arranged on both front and back surfaces of the module substrate 1352. Although eight semiconductor packages. 1354 are shown as being arranged on the front surface of the module substrate 1352 in FIG. 25, this is merely an example and the present inventive concepts are not limited thereto. The semiconductor module 1300 may further include a separate semiconductor package for controlling the semiconductor packages 1354.

At least one of the semiconductor packages 1354 may be the semiconductor package according to some of the embodiments described above. The module contact termninals 1358 may be formed of, for example, a metal, and have oxidation resistance. The module contact terminals 1358 may be variously set according to standards of the semiconductor module 1300. Therefore, in the present inventive concepts are not limited to the number of the illustrated module contact termninals 1358.

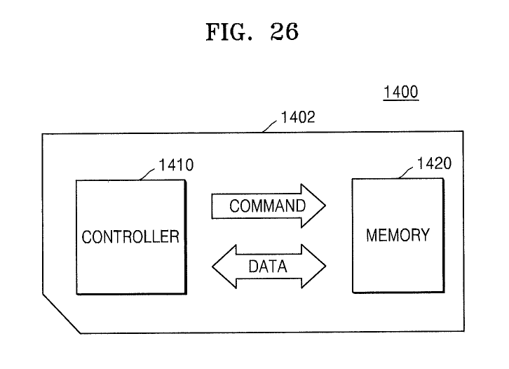

FIG. 26 is a schematic, block diagram of a card including a semiconductor package according to some embodiments of the present inventive concepts.

Specifically, a card 1400 may include, for example, a controller 1410 and a memory 1420, which are arranged on a circuit board 1402. The controller 1410 and the memory 1420 may exchange electrical signals with each other. For example, if the controller 1410 gives a command to the memory 1420, the memory 1420 may transmit data.

The memory 1420 or the controller 1410 may include the semiconductor package according to some embodiments of the present inventive concepts, that is, as described above. The card 1400 may include various cards, for example, a memory stick card, a smart media card (SM), a secure digital card (SD), a mini secure digital card (mini SD), or a multi-media card (MMC) or the like.

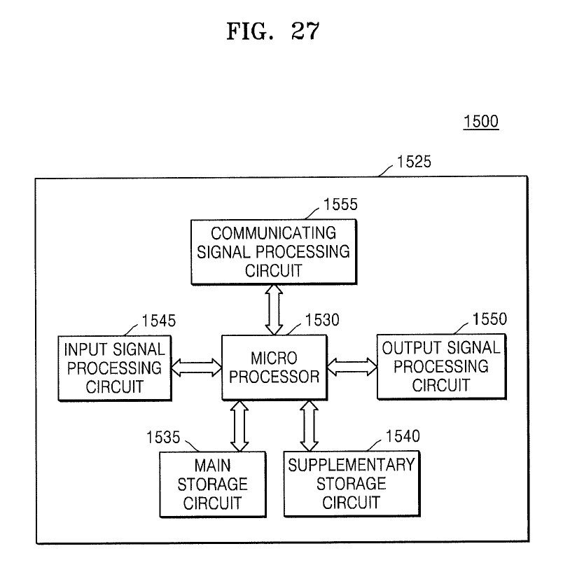

FIG. 27 is a schematic, block diagram of an electronic circuit board including a semiconductor package according to some embodiments of the present inventive concepts.

Specifically, an electronic circuit board 1500 includes a microprocessor 1530, a main storage circuit 1535 and a supplementary storage circuit 1540 communicating with the microprocessor 1530, an input signal processing circuit 1545 sending commands to the microprocessor 1530, an output signal processing circuit 1550 receiving commands from the microprocessor 1530, and a communicating signal processing circuit 1555 sending signals to and receiving signals from other circuit boards. The components stated above are arranged on a circuit board 1525. In FIG. 27, the arrows mean paths through which electrical signals can be transferred.

The microprocessor 1530 may receive and process various electrical signals, output processed results, and control other components of the electronic circuit board 1500. The microprocessor 1530 may include, for example, a central processing unit (CPU), a main control unit (MCU), and/or the like.

The main storage circuit 1535 may temporarily store data that is always or frequently required by the microprocessor 1530, or data before and after processing. Since the main storage circuit 1535 requires a fast response speed, the main storage circuit 1535 may include, for example, a semiconductor memory chip. More specifically, the main storage circuit 1535 may be a semiconductor memory referred to as a cache, and may include a static random access memory (SRAM), a dynamic random access memory (DRAM), a resistive random access memory (RRAM), and applications thereof, for example, a utilized RAM, a ferro-electric RAM, a fast cycle RAM, a phase changeable RAM, a magnetic RAM, and other semiconductor memories.

In addition, the main storage circuit 1535 may be volatile or nonvolatile, and the main storage circuit 1535 may include, for example, a random access memory. In some embodiments, the main storage circuit 1535 may include at least one semiconductor package or semiconductor module according to the inventive concepts, that is, the semiconductor packages or semiconductor modules as described above. The supplementary storage circuit 1540 is a mass storage device, and may be a nonvolatile semiconductor memory such as a flash memory, or be a hard disk drive using a magnetic field. Alternatively, the supplementary storage circuit 1540 may be a compact disk drive using light. The supplementary storage circuit 1540 may be used when the supplementary storage circuit 1540 needs to store massive data while not requiring a fast speed, as compared with the main storage circuit 1535. The supplementary storage circuit 1540 may be of random type or non-random type, and the supplementary storage circuit 1540 may include, for example, a nonvolatile storage device.

The supplementary storage circuit 1540 may include the semiconductor package or the semiconductor module according to the inventive concepts, that is, the semiconductor packages or semiconductor modules as described above. The input signal processing circuit 1545 may convert a command external to the electronic circuit board 1500 into an electrical signal, or transfer an electrical signal, which is transferred from the outside of the electronic circuit board 1500, to the microprocessor 1530.

The command or electrical signal transferred from the outside of the electronic circuit board 1500 may be an operation command, an electrical signal to be processed, or data to be stored. The input signal processing circuit 1545 may include, for example, a terminal signal processing circuit, which processes signals transferred from a keyboard, a mouse, a touch pad, an image recognizing device, various sensors or the like, an image signal processing circuit, which processes input image signals of a scanner, camera, various sensors or input signal interfaces, or the like. The input signal processing circuit 1545 may include the semiconductor package or the semiconductor module according to the inventive concepts, that is, the semiconductor packages or semiconductor modules as described above.

The output signal processing circuit 1550 may be a component for transmitting an electrical signal processed by the microprocessor 1530 to the outside of the electronic circuit board 1500. For example, the output signal processing circuit 1550 may be, for example, a graphic card, an image processor, an optical converter, a beam panel card, an interface circuit having various functions, or the like. The output signal processing circuit 1550 may include the semiconductor package or the semiconductor module according to the inventive concepts, that is, the semiconductor packages or semiconductor modules as described above.

The communication circuit 1555 is a component for directly sending electrical signals to and directly receiving electrical signals from other electronic systems or other circuit boards without use of the input signal processing circuit 1545 or the output signal processing circuit 1550. For example, the communication circuit 1555 may include, for example, a modem of a personal computer system, a LAN card, various interface circuits, or the like. The communication circuit 1555 may include the semiconductor package or the semiconductor module according to the inventive concepts, that is, the semiconductor packages or semiconductor modules as described above.

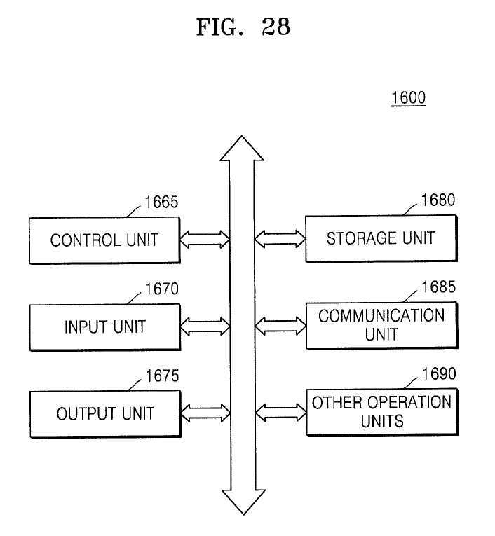

FIG. 28 is a schematic, block diagram of an electronic system including a semiconductor package according to some embodiments of the present inventive concepts.

Specifically, an electronic system 1600 includes, for example, a control unit 1665, an input unit 1670, an output unit 1675, and a storage unit 1680. The electronic system 1600 may further include a communication unit 1685 and/or other operation units 1690. The components of the electronic system 1600 may be connected by a bus.

The control unit 1665 may collectively control the electronic system 1600 and each of the components. The control unit 1665 may be, for example, a central processing unit or a central controlling unit, and may include the electronic circuit board 1500 of FIG. 27. In addition, the control unit 1665 may include the semiconductor package or the semiconductor module according to the inventive concepts, that is, the semiconductor packages or semiconductor modules as described above.

The input unit 1670 may send electrical command signals to the control unit 1665. The input unit 1670 may include, for example, a keyboard, a keypad, a mouse, a touch pad, an image recognizer such as a scanner, various input sensors, or the like. The input unit 1670 may include the semiconductor package or the semiconductor module according to the inventive concepts, that is, the semiconductor packages or semiconductor modules as described above.

The output unit 1675 may receive electrical signals from the control unit 1665, and output results processed by the electronic system 1600. The output unit 1675 may include, for example, a monitor, a printer, a beam projector, various mechanical devices or the like. The output unit 1675 may include the semiconductor package or the semiconductor module according to the inventive concepts, that is, the semiconductor packages or semiconductor modules as described above.

The storage unit 1680 may be a component for temporarily or permanently storing electrical signals which are to be processed or have been processed by the control unit 1665. The storage unit 1680 may be physically or electrically connected or coupled to the control unit 1665. The storage unit 1680 may include, for example, a semiconductor memory, a magnetic storage device such as a hard disk, an optical storage device such as a compact disk, or other servers having a data storing function, or the like. In addition, the storage unit 1680 may include the semiconductor package or the semiconductor module according to the inventive concepts, that is, the semiconductor packages or semiconductor modules as described above.

The communication unit 1685 may receive electrical command signals from the control unit 1665, and send electrical signals to or receive electrical signals from other electronic systems. The communication unit 1685 may include, for example, a wired transceiver such as a modem or a LAN card, a wireless transceiver such as a WiBro interface, an infrared port, or the like. In addition, the communication unit 1685 may include the semiconductor package or the semiconductor module according to the inventive concepts, that is, the semiconductor packages or semiconductor modules as described above.

The other operation units 1690 may perform physical or mechanical operations according to commands of the control unit 1665. For example, the other operation units 1690 may be components performing mechanical operations, such as plotters, indicators, up/down operators, or the like. The electronic system 1600 may include, for example, a computer, a network server, a network printer, a scanner, a wireless controller, a terminal for mobile communications, a switching system, other electronic devices performing programmed operations, or the like.

In addition, the electronic system 1600 may be used for, for example, mobile phones, MP3 players, navigation systems, portable multimedia players (PMPs), solid state disks (SSDs), household appliances, or the like.

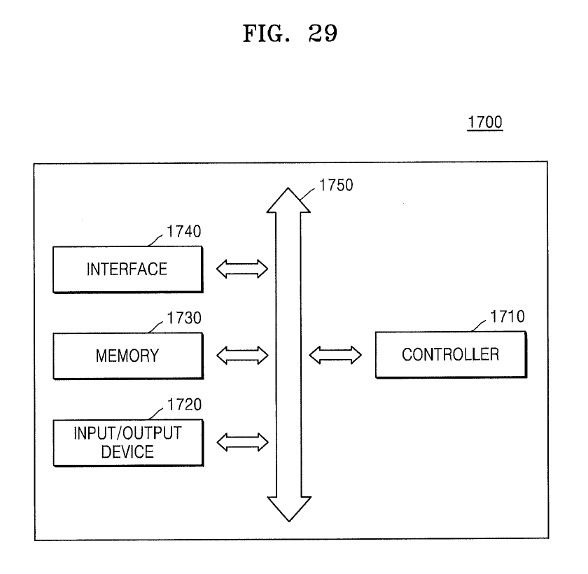

FIG. 29 is a schematic, block diagram of an electronic system including a semiconductor package according to some embodiments of the present inventive concepts.

Specifically, an electronic system 1700 may include, for example, a controller 1710, an input/output device 1720, a memory 1730, and an interface 1740 connected by a bus 1750. The electronic system 1700 may be, for example, a mobile system or a system for transmitting or receiving information. The mobile system may be, for example, a PDA, a portable computer, a web tablet, a wireless phone, a mobile phone, a digital music player, a memory card, or the like.

The controller 1710 may serve to execute programs and to control the electronic system 1700. The controller 1710 may include the semiconductor package according to the inventive concepts, that is, the semiconductor packages or semiconductor modules as described above. The controller 1710 may be, for example, a microprocessor, a digital signal processor, a microcontroller, or a device that is similar thereto.

The input/output device 1720 may be used to input or output data of the electronic system 1700. The electronic system 1700 may be connected to devices external to the electronic system 1700, for example, a personal computer or a network, by using the input/output device 1720, and, thus, exchange data with the external devices. The input/output device 1720 may be, for example, a keypad, a keyboard, a display, or the like.

The memory 1730 may store codes and/or data for operations of the controller 1710, and/or may store data processed by the controller 1710. The memory 1730 may include the semiconductor package according to the inventive concepts, that is, the semiconductor packages or semiconductor modules as described above. The interface 1740 may be a data transmitting path between the electronic system 1700 and other devices external to the electronic system 1700. The controller 1710, the input/output device 1720, the memory 1730, and the interface 1740 may communicate with each other through the bus 1750.

The electronic system 1700 may be used for, for example, mobile phones, MP3 players, navigation systems, portable multimedia players (PMPs), solid state disks (SSDs), household appliances or the like.

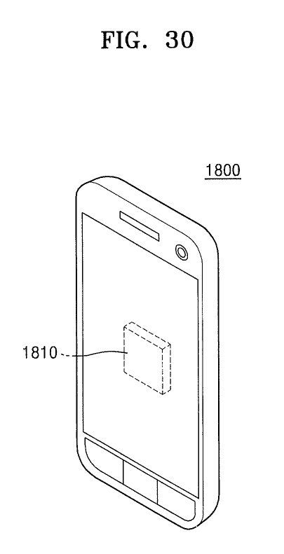

FIG. 30 is a schematic, perspective view of an electronic device including a semiconductor package according to some embodiments of the present inventive concepts.

Specifically, FIG. 30 illustrates an example in which the electronic system 1700 of FIG. 29 is applied to a mobile phone 1800. The mobile phone 1800 may include, for example, a system-on-chip 1810. The system-on-chip 1810 may include the semiconductor package according to the inventive concepts, that is, the semiconductor packages or semiconductor modules as described above. Since the mobile phone 1800 may include the system-on-chip 1810 which may include, for example, a main functional block exhibiting relatively high performance, the mobile phone 1800 may exhibit relatively high performance. In addition, since the system-on-chip 1810 may exhibit relatively high performance while having the same area as other general chips, the mobile phone 1800 may exhibit relatively high performance while having a minimized size.

While the inventive concepts have been particularly shown and described with reference to embodiments thereof, it will be understood that various changes in form and details may be made therein without departing from the spirit and scope of the following claims.

1. A molding apparatus for semiconductor package fabrication, the molding apparatus comprising:
a bottom mold on which a molding object can be mounted;
a top mold on the bottom mold comprising the molding object that is mounted; and
a side mold on one side of the bottom mold and the top mold, the side mold having a plurality of air vent holes,
wherein a cavity is provided between the bottom mold and the top mold, the cavity capable of having a molding material injected therein and made to flow therein.

2. (canceled)

3. (canceled)

4. The molding apparatus according to claim 1, wherein a molding material supplier capable of supplying the molding material is provided in a central portion of one of the bottom mold and the top mold.

5. The molding apparatus according to claim 4, wherein the side mold is located on both sides of the bottom mold and the top mold.

6. The molding apparatus according to claim 4, wherein the side mold is located around the bottom mold and the top mold.

7. The molding apparatus according to claim 1, wherein the side mold comprises a side mold body, and the air vent holes having a same size are arranged in the side mold body at regular intervals in a direction perpendicular to a flow direction of the molding material.

8. The molding apparatus according to claim 1, wherein each of the air vent holes of the side mold comprises an air vent controlling member that is detachable.

9. The molding apparatus according to claim 8, wherein the air vent controlling member comprises an air vent controlling body capable of being inserted into one of the plurality air vent holes, and a sub-air vent hole provided in the air vent controlling body, and
the sub-air vent holes provided in the air vent controlling bodies have different sizes.

10. The molding apparatus according to claim 9, wherein each sub-air vent hole has one of a circular, an elliptical, and an oval shape.

11. The molding apparatus according to claim 9, wherein the air vent holes comprise a chamber portion having an inclined inner wall and a cylindrical portion, and
the air vent controlling body comprises a cylindrical body inserted into the cylindrical portion, and a tap-type body inserted into the chamber portion.

12. The molding apparatus according to claim 11, wherein a locking member for fastening the air vent controlling body to the air vent holes is provided around the cylindrical body.

13. A molding apparatus for semiconductor package fabrication, the molding apparatus comprising:
a bottom mold on which a molding object can be mounted;
a top mold on the bottom mold comprising the molding object that is mounted;
a molding material supplier capable of supplying a molding material into a cavity between the bottom mold and the top mold;
a side mold on one side of the bottom mold and the top mold, the side mold having a plurality of air vent holes; and
an air sucking unit connected to the air vent holes of the side mold.

14. The molding apparatus according to claim 13, wherein the bottom mold comprises a bottom mold body, and a bottom cavity on a surface of the bottom mold body in which the molding object can be mounted.

15. The molding apparatus according to claim 13, wherein the top mold comprises a top mold body, and a top cavity on a surface of the top mold body facing the bottom mold into which the molding material can be injected.

16. The molding apparatus according to claim 13, wherein the molding material supplier is provided on one of one side of the bottom mold, in a central portion of the bottom mold, and in a central portion of the top mold.

17. The molding apparatus according to claim 13, wherein the air sucking unit comprises an exhaust pipe connected to the air vent holes, and a vacuum generating means connected to the exhaust pipe.

18. The molding apparatus according to claim 13, wherein each of the air vent holes of the side mold comprises an air vent controlling member that is detachable, and the air vent controlling members respectively comprise sub-air vent holes having different sizes.

19-30. (canceled)

31. A molding apparatus for semiconductor package fabrication, the molding apparatus comprising:
a bottom mold on which a molding object can be mounted;
a top mold on the bottom mold;
a side mold on at least one side of the bottom mold and the top mold;
a cavity in at least one of the top mold and the bottom mold; and
a plurality of air vent holes in the side mold, the plurality of air vent holds being arranged at regular intervals along the side mold.

32. The molding apparatus according to claim 31, wherein each of the plurality of air vent holes in the side mold comprises an air vent controlling member that is detachable.

33. The molding apparatus according to claim 32, wherein the air vent controlling member comprises an air vent controlling body capable of being inserted into one of the plurality air vent holes, and a sub-air vent hole provided in the air vent controlling body.

34. The molding apparatus according to claim 31, wherein a molding material supplier capable of supplying a molding material is provided in a central portion of one of the bottom mold and the top mold.

35. (canceled)
